(19) United States
(12) Patent Application Publication
(10) Pub. No.: US 2010/0085996 A1
(43) Pub. Date: Apr. 8, 2010

(54) NITRIDE SEMICONDUCTOR LASER DEVICE AND ITS MANUFACTURING METHOD

(75) Inventor: Yuji Matsuno, Moriguchi-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: SANYO ELECTRIC CO., LTD., Moriguchi-shi, Osaka (JP)

(21) Appl. No.: 12/445,317

(22) PCT Filed: Oct. 15, 2007
(86) PCT No.: PCT/JP2007/070059

§ 371 Date: Apr. 13, 2009

(30) Foreign Application Priority Data
Oct. 17, 2006 (JP) 2006-282091
Oct. 19, 2006 (JP) 2006-284837

(51) Int. Cl. H01S 5/02; H01L 33/00; H01S 5/00

(52) U.S. Cl. 372/46.01; 438/42; 257/E33.013

(57) ABSTRACT

A method for manufacturing a nitride semiconductor laser device with suppression of deterioration of the yield and good light emission characteristic. The method comprises a step of forming nitride semiconductor layers on an n-type GaN substrate, a step of forming a ridge composed of a p-type clad layer and a contact layer and extending in the [1-100] direction, a step of forming a trench made in the top surface of the n-type GaN substrate by applying a YAG laser beam and extending in the direction ([11-20] direction) perpendicular to the ridge, and a step of forming end surfaces of a resonator by dividing the n-type GaN substrate from the trench. The step of forming a trench includes a substep of forming the end of the trench in a region a predetermined distance W2 (about 50 μm to about 200 μm) apart from the side face of the ridge.

### TECHNICAL FIELD

The present invention relates to a nitride semiconductor laser device and its manufacturing method, and particularly relates to a nitride semiconductor laser device and its manufacturing method in which a plurality of nitride semiconductor layers including a light-emitting layer is formed on a substrate.

### BACKGROUND ART

Nitride semiconductor laser devices are conventionally known in which a nitride semiconductor layer is formed on a substrate (e.g., see Patent Reference 1).

A nitride semiconductor laser device is disclosed in Patent Reference 1 in which a plurality of nitride semiconductor layers is formed on a GaN substrate, and an optical waveguide that extends parallel to the <1-100> direction of the substrate is formed inside the nitride semiconductor layers. The nitride semiconductor laser device is formed into a chip shape by a primary cleave along the <11-20> direction of the substrate and then a secondary cleave along the <1-100> direction of the substrate. Specifically, the primary cleave is carried out by using a diamond needle to form a cleave guide groove that extends in the <11-20> direction of the substrate in a region other than directly above the optical waveguide of the device, and thereafter applying stress to the device. The substrate is thereby divided along the cleave guide groove as the starting point, and end surfaces of a resonator are formed in which the region of the optical waveguide periphery is flat. Also, the second cleave is carried out by using a diamond needle to form a cleave guide groove that extends in the <1-100> direction of the substrate in the surface or the reverse surface of the device, and thereafter applying stress to the device. The substrate is thereby divided along the cleave guide groove as the starting point, and a chip-shaped nitride semiconductor laser device is formed.
[Patent Reference 1] Japanese Laid-open Patent Application No. 2003-17791

### DISCLOSURE OF THE INVENTION

### Problems the Invention Is Intended To Solve

However, with the nitride semiconductor laser device described in Patent Reference 1 noted above, it is difficult to increase the depth of the cleave start groove because the cleave guide groove as the starting point for division is formed using a diamond needle. For this reason, considerable stress must be applied when the substrate is divided by applying stress to the device, and in such a case there is a drawback in that it is difficult to divide the device using the cleave guide groove as a starting point. As a result, there is a problem in that the light-emission characteristics of the nitride semiconductor laser device are reduced because the substrate is divided in a position other than the cleave guide groove.

There is also a drawback in that the manufacturing yield of the nitride semiconductor laser device is reduced at the same time because division of the substrate in a position other than the cleave guide groove is a division defect.

The present invention was contrived in order to solve problems such as those described above, and an object of the present invention is to provide a method for manufacturing a nitride semiconductor laser device having good light-emission characteristics and that can limit a reduction in yield.

Another object of the present invention is to provide a nitride semiconductor laser device having good light-emission characteristics and that can limit a reduction in yield.

### Means for Solving the Abovementioned Problems

In order to achieve the above-stated objects, the method for manufacturing a nitride semiconductor laser device according to a first aspect of the present invention comprises a step for forming a plurality of nitride semiconductor layers including a light-emitting layer on an upper surface of a substrate; a step for forming an electric current channel extending in a predetermined direction on at least one of the plurality of nitride semiconductor layers; a step for forming a trench extending in a direction orthogonal to the electric current channel on the upper surface of the substrate by irradiating laser beam on the upper surface of the nitride semiconductor layers; and a step for forming a resonator end face by dividing the substrate using the trench as a starting point. The step for forming the trench includes a step for forming end parts of the trench in a region set at a predetermined distance from the electric current channel.

In the method for manufacturing a nitride semiconductor laser device according to the first aspect, a trench that extends in the direction orthogonal to the electric current channel is formed on the substrate by irradiating laser beam on the upper surface of the nitride semiconductor layer, and the end parts of the trench are formed in a region set at a predetermined distance from the electric current channel, whereby the trench is not formed in a region near the electric current channel. Therefore, the formation of very small longitudinal lines caused by the trench can be reduced in the region below the region near the electric current channel of the end face of the resonator when the substrate is divided using the trench as a starting point. In other words, the formation of very small longitudinal lines caused by the trench can be reduced in the region about the periphery of the optical waveguide below the electric current channel in the end surface of the resonator. A groove that extends in the direction orthogonal to the electric current channel is formed on the surface of the substrate by irradiating a laser beam on the upper surface of the nitride semiconductor layer, whereby the trench can be formed more deeply than the case in which the trench is formed on the upper surface of the substrate using a diamond needle. Accordingly, the substrate can be rectilinearly divided along a desired division line without making a division on a line inclined 60° from the desired division line or along another line, even when a hexagonal substrate (e.g., GaN substrate, or the like) is used in which a direction that is 60° from the cleave direction is an equivalent cleave direction because the stress applied to the device can be reduced when the substrate is divided by applying stress to the device.

The end surfaces of the resonator can thereby be flatly formed and it is possible to reduce the occurrence of defects in which very small longitudinal lines or the like are formed in the region about the periphery of the optical waveguide of the end surfaces of the resonator due the substrate being divided on lines inclined 60° from the desired division line or along other lines. Therefore, the reflectivity of the end surfaces of the resonator can be improved because the region about the periphery of the optical waveguide of the end surfaces of the resonator can be formed into a mirror surface. As a result, a nitride semiconductor laser device having good light emission characteristics can be manufactured. As described above, it is also possible to limit a reduction in yield at the same time during manufacture by reducing the formation of very small longitudinal lines in the region about the periphery of the optical waveguide of the end surfaces of the resonator.

In the first aspect, the end parts of the trench are formed in a region set at a predetermined distance from the electric current channel, as described above, whereby the region about the periphery of the electric current channel can be made less liable to incur heat damage from the laser beam irradiation when the trench is formed by irradiating laser beam. Accordingly, it is possible to reduce the occurrence of defects in which light emission characteristics are reduced due to heat damage incurred in the region about the periphery of the electric current channel. The portions acting as the end parts of the electric current channel following substrate division are moved in mutually separating directions when the substrate is divided by forming the trench on the upper surface of the substrate and using the trench as a starting point. Therefore, defects in which the portions acting as the end parts of the electric current channel after substrate separation interfere with each other and the electric current channel deforms do not occur in contrast to the case in which the trench is formed on the lower surface of the substrate. For this reason, the occurrence of defects in which the light emission characteristics are reduced due to a deformation of the end parts of the electric current channel after substrate division can be reduced.

In the method for manufacturing a nitride semiconductor laser device according to the first aspect, the step for forming the trench preferably includes a step for forming the length of the trench in a direction orthogonal to the electric current channel so that the length gradually increases from the bottom of the trench toward the upper surface of the substrate. In accordance with such a configuration, it is possible to rectilinearly divide a substrate in a simple manner along a desired division line when the end parts of the trench are formed in a region set at a predetermined distance from the electric current channel because the substrate can be divided in a simple manner using the trench as a starting point. The reflectivity of the end surfaces of the resonator can be easily improved because the region about the periphery of the optical waveguide of the end surfaces of the resonator can thereby be formed into a mirror surface. As a result, a nitride semiconductor laser device having good light emission characteristics can be easily manufactured.

In the method for manufacturing a nitride semiconductor laser device according to the first aspect, the substrate preferably includes a nitride semiconductor substrate. In accordance with such a configuration, the crystallographic axes of the nitride semiconductor substrate and the plurality of nitride semiconductor layers including the light-emitting layer formed on the nitride semiconductor substrate can be made to match. Therefore, the nitride semiconductor substrate and the nitride semiconductor layers including the light-emitting layer can be divided at a readily dividable uniform crystallographic axis. A region about the periphery of the optical waveguide of the end surfaces of the resonator can be readily formed into a mirror surface because the nitride semiconductor laser device can be rectilinearly divided in a simple manner along a desired division line. As a result, the reflectivity of the end surfaces of the resonator can be more readily improved.

In this case, it is preferred that the nitride semiconductor substrate have a periodically arranged high-displacement density region and low-displacement density region that extend along the electric current channel; the step for forming the electric current channel include a step for forming the electric current channel on the low-displacement density region of the nitride semiconductor substrate; and the step for forming the trench include a step for forming the trench so as to be transverse to the high-displacement density region by irradiating laser beam. In accordance with such a configuration, the substrate can be rectilinearly divided in a simple manner along a desired division line even when a nitride semiconductor laser substrate provided with a periodically arranged high-displacement density region and low-displacement density region is used. In other words, it is difficult to make a rectilinear cleave because the crystal is discontinuous at the boundary between the high-displacement density region and the low-displacement density region. However, even when the crystal is discontinuous at the boundary between the high-displacement density region and the low-displacement density region, the substrate can be rectilinearly cleaved (divided) in a simple manner by dividing the substrate along the trench because the trench is formed so as to transverse the high-displacement density region, whereby the trench is also formed at the boundary between the high-displacement density region and the low-displacement density region.

The method for manufacturing a nitride semiconductor laser device according to a second aspect of the present invention comprises a step for forming a plurality of nitride semiconductor layers including a light-emitting layer on a substrate; a step for forming an electric current channel extending in a predetermined direction on at least one of the plurality of nitride semiconductor layers; a step for forming a pair of end surfaces of a resonator orthogonal to the electric current channel; a step for forming a trench that extends parallel to the electric current channel part on the reverse surface of the substrate by irradiating laser beam; and a step for dividing the substrate using the trench as a starting point. The step for forming the trench includes a step for forming end parts of the trench in a region set at a predetermined distance from the end surfaces of the resonator.

In the method for manufacturing a nitride semiconductor laser device according to the second aspect, a trench that extends parallel to the electric current channel on the reverse surface of the substrate is formed by irradiating laser beam as described above, whereby the stress to be applied to the device can be reduced in the case that the substrate is divided by applying stress to the device, because the trench can be deeply formed in comparison with the case in which the trench is formed on the reverse surface of the substrate using a diamond needle. Accordingly, the substrate can be readily divided along a desired division line because the substrate can be readily divided using the trench thus formed as a base point. A reduction in yield can thereby be limited during manufacture of the nitride semiconductor laser device.

Laser beam can be prevented from being irradiated on the end surfaces of the resonator by forming the end parts of the trench in a region set at a predetermined distance from the end surfaces of the resonator, i.e., the reverse surface of the substrate by irradiating laser beam, which is different from the case in which a trench is formed until the end surfaces of the resonator are reached by the irradiation of laser beam. Accordingly, the region near the end surfaces of the resonator of the substrate can be prevented from being damaged by excessive heat. In other words, the region near the end surfaces of the resonator of the substrate is damaged by excessive heat in the case that laser beam is irradiated onto the end surfaces of the resonator, because the surface area irradiated by the laser beam is greater in comparison with irradiating laser beam on the reverse surface of the substrate. For this reason, the region near the end surfaces of the resonator of the substrate can be prevented from being damaged by excessive heat because the laser beam is prevented from being irradiated onto the end surfaces of the resonator. Chipping in the region near the end surfaces of the resonator of the substrate can thereby be prevented from occurring when the substrate is divided using the trench as a starting point. Therefore, the region about the periphery of the optical waveguide of the end surfaces of the resonator can be maintained as a mirror surface because defects in which the end surfaces of the resonator are damaged by flying chips can be prevented. As a result, a nitride semiconductor laser device having good light emission characteristics can be manufactured because the reflectivity of the end surfaces of the resonator can be prevented from being reduced.

In the second aspect, the region near the end surfaces of the resonator of the substrate can be prevented from being damaged by excessive heat by forming the end parts of the trench in a region set at a predetermined distance from the end surfaces of the resonator, i.e., the reverse surface of the substrate, by irradiating laser beam as described above. Accordingly, it is possible to reduce the occurrence of defects in which dust, chips, and other unwanted matter are generated during trench formation in the region near the end surfaces of the resonator of the substrate when the region near the end surfaces of the resonator of the substrate is damaged by excessive heat. For this reason, it is possible to reduce the occurrence of defects in which the end surfaces of the resonator are damaged by deposits of unwanted matter, because dust, chips, and other unwanted matter generated during formation of the trench can be prevented from being deposited on the end surfaces of the resonator. Since the region near the optical waveguide of the end surfaces of the resonator can thereby be maintained as a mirror surface, a reduction in the reflectivity of the end surfaces of the resonator can be limited. As a result, good light emission characteristics can thereby be obtained as well.

In the second aspect, laser beam can be prevented from irradiating an adhesive sheet or the like for securing the device and applied to the lower surface (the surface on the opposite side of the surface in which the trench will be formed) of the device because the irradiation of the laser beam can be stopped at the position of the end parts of the trench by forming the end parts of the trench in a region set at a predetermined distance from the end surfaces of the resonator. Accordingly, the sheet or the like can be prevented from being burned when the sheet or the like is irradiated by the laser beam. Therefore, the occurrence of unwanted matter or the like due to the sheet or the like being burned can be prevented. Since it is thereby possible to reduce deposits of unwanted matter or the like generated by the sheet or the like being burned on the end surfaces of the resonator, it is possible to reduce the occurrence of defects in which the end surfaces of the resonator are damaged due to deposits of unwanted matter or the like on the end surfaces of the resonator. As a result, a reduction in the reflectivity of the end surfaces of the resonator can thereby be limited because the region about the periphery of the optical waveguide of the end surfaces of the resonator can be maintained as a mirror surface.

In the method for manufacturing a nitride semiconductor laser device according to the second aspect, it is preferred that the step for forming the trench include a step for forming the length of the trench in the direction parallel to the electric current channel part so that the length gradually increases from the bottom of the trench toward the reverse surface of the substrate. In accordance with such a configuration, the substrate can be readily divided along a desired division line and the occurrence of chipping at the edges after division can be reduced in a simple manner even when the end parts of the trench are formed in a region set at a predetermined distance from the end surfaces of the resonator because the substrate can be more readily divided using the trench as a starting point. A reduction in yield during manufacture can thereby be limited in a simple manner and a nitride semiconductor laser device having good light emission characteristics can be readily manufactured.

In the method for manufacturing a nitride semiconductor laser device according to the second aspect, it is preferred that the substrate include a nitride semiconductor substrate. In accordance with such a configuration, the crystallographic axes of the nitride semiconductor substrate and the plurality of nitride semiconductor layers including the light-emitting layer formed on the nitride semiconductor substrate can be made to match. Therefore, the nitride semiconductor substrate and the nitride semiconductor layers including the light-emitting layer can be divided at a readily dividable uniform crystallographic axis. The nitride semiconductor laser device can thereby be readily divided along a desired division line and the occurrence of chipping at the edges after division can be more readily reduced.

The nitride semiconductor laser device according to a third aspect of the present invention comprises a plurality of nitride semiconductor layers including a light-emitting layer, the nitride semiconductor layers being formed on a substrate; an electric current channel extending in a predetermined direction, the electric current channel being formed on at least one of the plurality of nitride semiconductor layers; a pair of end surfaces of a resonator orthogonal to the electric current channel; and a substrate-dividing notch formed in at least a part of the vicinity of the end surfaces of a resonator in an upper surface of the substrate by irradiating a laser beam. The end parts of the substrate-dividing notch are formed in a region set at a predetermined distance from the electric current channel.

In the nitride semiconductor laser device according to the third aspect, a substrate-dividing notch is formed in at least a part of the vicinity of the end surfaces of a resonator in an upper surface of the substrate by irradiating a laser beam as described above, and the end parts of the substrate-dividing notch are formed in a region set at a predetermined distance from the electric current channel, whereby very small longitudinal lines caused by the substrate-dividing notch can be reduced in the region below the region near the electric current channel of the end surfaces of the resonator when the substrate is divided, because the substrate-dividing notch is not formed in the region near the electric current channel. In other words, the formation of very small longitudinal lines caused by the substrate-dividing notch can be reduced in the region about the periphery of the optical waveguide below the electric current channel in the end surfaces of the resonator. A substrate-dividing notch is formed in at least a part of the vicinity of the end surfaces of the resonator in the upper surface of the substrate by irradiating laser beam, whereby the substrate-dividing notch can be formed deeply in comparison with the case in which the substrate-dividing notch is formed on the upper surface of the substrate using a diamond needle. Therefore, stress applied to the device can be reduced when the substrate is divided by applying stress to the device.

For this reason, the substrate can be rectilinearly divided along a desired division line without making a division on a line inclined 60° from the desired division line or along another line, even when a GaN substrate or another hexagonal substrate is used. Therefore, the end surfaces of the resonator can be flatly formed, and it is possible to reduce the occurrence of defects in which very small longitudinal lines or the like are formed in the region about the periphery of the optical waveguide of the end surfaces of the resonator due to the substrate being divided at a line that is 60° from the desired dividing line. The reflectivity of the end surfaces of the resonator can be improved because the region about the periphery of the optical waveguide of the end surfaces of the resonator can be formed as a mirror surface. As a result, a nitride semiconductor laser device having good light emission characteristics can be obtained. A reduction in yield during manufacturing can be limited by reducing the formation of very small longitudinal lines in the region about the periphery of the optical waveguide of the end surfaces of the resonator, as described above. The end parts of the substrate-dividing notch are formed in a region set at a predetermined distance from the electric current channel, whereby the region about the periphery of the electric current channel can be prevented from being damaged due to excess heat from the irradiation of laser beam, even in the case that the substrate-dividing notch is formed by irradiating laser beam. Therefore, it is possible to reduce the occurrence of defects in which the light emission characteristics are reduced due to the region about the periphery of the electric current channel being damaged by heat.

In the nitride semiconductor laser device according to the third aspect, it is preferred that the substrate-dividing notch be configured so that the length in the direction orthogonal to the electric current channel gradually increases from the bottom of the substrate-dividing notch toward the upper surface of the substrate. In accordance with such a configuration, the region about the periphery of the optical waveguide of the end surfaces of the resonator can be readily formed as a mirror surface because the substrate can be rectilinearly divided in a simple manner along a desired division line even when the end parts of the substrate-dividing notch are formed in a region set at a predetermined distance from the electric current channel. Since the reflectivity of the end surfaces of the resonator can thereby be improved in a simple manner, a nitride semiconductor laser device having good light emission characteristics can be readily obtained.

The nitride semiconductor laser device according to a fourth aspect of the present invention comprises a plurality of nitride semiconductor layers including a light-emitting layer, the nitride semiconductor layers being formed on a substrate; an electric current channel extending in a predetermined direction, the electric current channel being formed on at least one of the plurality of nitride semiconductor layers; a pair of end surfaces of a resonator orthogonal to the electric current channel; a side end surface orthogonal to the end surfaces of the resonator; and a substrate-dividing notch extending parallel to the electric current channel, the substrate-dividing notch being formed in at least a part of the vicinity of the side end surface in a reverse surface of the substrate. The end parts of the substrate-dividing notch are formed in a region set at a predetermined distance from end surfaces of the resonator.

In the nitride semiconductor laser device according to the fourth aspect, a substrate-dividing notch extending parallel to the electric current channel is formed in at least a part of the vicinity of the side end surface in the reverse surface of the substrate by irradiating a laser beam, whereby the substrate-dividing notch can be more deeply formed than the case in which a substrate-dividing notch is formed using a diamond needle. Therefore, stress applied to the device can be reduced when the substrate is divided by applying stress to the device. Accordingly, the substrate can be divided in a simple manner along a desired division line because the substrate can be readily divided using the substrate-dividing notch as a starting point. A reduction in yield during manufacture of the nitride semiconductor laser device can thereby be limited. The end parts of the substrate-dividing notch are formed in a region set at a predetermined distance from the end surfaces of the resonator by irradiating a laser beam, whereby laser beam can be prevented from irradiating the end surfaces of the resonator, which is different from the case in which the substrate-dividing notch is formed as far as the end surfaces of the resonator by irradiating a laser beam. Therefore, the region near the end surfaces of the resonator of the substrate can be prevented from being damaged by excessive heat. For this reason, it is possible to reduce the occurrence of defects in which the end surfaces of the resonator are damaged by flying chips because the occurrence of chipping in the region near the end surfaces of the resonator of the substrate can be reduced when the substrate is divided using the substrate-dividing notch as a starting point. Since the region about the periphery of the optical waveguide of the end surfaces of the resonator can thereby be maintained as a mirror surface, a reduction in the reflectivity of the end surfaces of the resonator can be limited. As a result, a nitride semiconductor laser device having good light emission characteristics can be obtained.

In the fourth aspect, the region near the end surfaces of the resonator of the substrate can be prevented from being damaged due to excessive heat by forming the end parts of the substrate-dividing notch in a region set at a predetermined distance from the end surfaces of the resonator by irradiating a laser beam. Therefore, it is therefore possible to reduce the occurrence of defects in which dust, chips, and other unwanted matter are generated during formation of the substrate-dividing notch in the region near the end surfaces of the resonator of the substrate due to the region near the end surfaces of the resonator of the substrate being damaged by excessive heat. For this reason, it is possible to reduce the occurrence of defects in which the end surfaces of the resonator are damaged by deposits of unwanted matter, because dust, chips, and other unwanted matter generated during formation of the substrate-dividing notch can be prevented from being deposited on the end surfaces of the resonator. Since the region near the optical waveguide of the end surfaces of the resonator can thereby be maintained as a mirror surface, a reduction in the reflectivity of the end surfaces of the resonator can be limited. As a result, a nitride semiconductor laser device having good light emission characteristics can thereby be obtained as well.

In the nitride semiconductor laser device according to the fourth aspect, it is preferred that the substrate-dividing notch be configured so that the length in the direction parallel to the electric current channel gradually increases from the bottom of the substrate-dividing notch toward the reverse surface of the substrate. In accordance with such a configuration, the substrate can be readily divided along a desired division line and the occurrence of chipping at the edges after division can be reduced in a simple manner even when the end parts of the substrate-dividing notch are formed in a region set at a predetermined distance from the end surfaces of the resonator because the substrate can be more readily divided using the substrate-dividing notch as a starting point. A reduction in yield during manufacture can thereby be limited in a simple manner and a nitride semiconductor laser device having good light emission characteristics can be obtained.

In the nitride semiconductor laser device according to the third and fourth aspects, the substrate preferably includes a nitride semiconductor substrate. In accordance with such a configuration, the crystallographic axes of the nitride semiconductor substrate and the plurality of nitride semiconductor layers including the light-emitting layer formed on the nitride semiconductor substrate can be made to match. Therefore, the nitride semiconductor substrate and the nitride semiconductor layers including the light-emitting layer can be divided at a readily dividable uniform crystallographic axis. The nitride semiconductor laser device can thereby be readily divided along a desired division line and the occurrence of chipping at the edges after division can be more readily reduced.

### Effect of the Invention

As described above, in accordance with the present invention, a reduction in yield can be limited and it is possible to readily obtain a nitride semiconductor laser device having good light emission characteristics and a method of manufacturing the same.

### BRIEF DESCRIPTION OF THE DRAWINGS

FIG. 1 is an overall perspective view of the nitride semiconductor laser device according to the first embodiment of the present invention as seen from the direction along which the electric current channel (ridge) extends;

FIG. 2 is a front view of the nitride semiconductor laser device according to the first embodiment of the present invention shown in FIG. 1 as seen from the direction along which the electric current channel (ridge) extends;

FIG. 3 is a side view of the nitride semiconductor laser device according to the first embodiment shown in FIGS. 1 and 2 as seen from the direction in which the notch is formed;

FIG. 4 is a cross-sectional view of the active layer of the nitride semiconductor laser device according to the first embodiment of the present invention shown in FIG. 1;

FIG. 5 is a plan view of the nitride semiconductor laser device according to the first embodiment of the present invention shown in FIG. 1 as seen from the upper surface;

FIG. 6 is a plan view showing the n-type GaN substrate used in the nitride semiconductor laser device according to the first embodiment of the present invention shown in FIG. 1;

FIG. 7 is a cross-sectional view for describing the method for manufacturing a nitride semiconductor laser device according to the first embodiment of the present invention shown in FIG. 1;

FIG. 8 is a cross-sectional view for describing the method for manufacturing a nitride semiconductor laser device according to the first embodiment of the present invention shown in FIG. 1;

FIG. 9 is a cross-sectional view for describing the method for manufacturing a nitride semiconductor laser device according to the first embodiment of the present invention shown in FIG. 1;

FIG. 10 is a cross-sectional view for describing the method for manufacturing a nitride semiconductor laser device according to the first embodiment of the present invention shown in FIG. 1;

FIG. 11 is a cross-sectional view for describing the method for manufacturing a nitride semiconductor laser device according to the first embodiment of the present invention shown in FIG. 1;

FIG. 12 is a cross-sectional view for describing the method for manufacturing a nitride semiconductor laser device according to the first embodiment of the present invention shown in FIG. 1;

FIG. 13 is a plan view showing a state prior to making a primary cleave of the nitride semiconductor laser device according to the first embodiment of the present invention shown in FIG. 1;

FIG. 14 is a schematic view for describing the method for forming a trench by irradiating a YAG laser beam;

FIG. 15 is a plan view showing a state in which a trench has been formed by irradiating a YAG laser beam;

FIG. 16 is a cross-sectional view along the line 100-100 of the region enclosed by the broken line of FIG. 15;

FIG. 17 is a view for describing the shape of the trench formed by irradiating a YAG laser beam;

FIG. 18 is a plan view showing the device divided in a bar shape by the primary cleave;

FIG. 19 is a view for describing the shape of the trench according to examples 1 to 6;

FIG. 20 is a view for describing the shape of the trench according to a comparative example;

FIG. 21 is an overall perspective view of the nitride semiconductor laser device according to the second embodiment of the present invention as seen from the direction along which the electric current channel (ridge) extends;

FIG. 22 is a cross-sectional view along the line 200-200 of FIG. 21;

FIG. 23 is a side view of the nitride semiconductor laser device according to the second embodiment of the present invention shown in FIG. 21;

FIG. 24 a plan view of the nitride semiconductor laser device according to the second embodiment of the present invention shown in FIG. 21 as seen from the reverse surface;

FIG. 25 is a cross-sectional view for describing the method for manufacturing a nitride semiconductor laser device according to the second embodiment of the present invention shown in FIG. 21;

FIG. 26 is a plan view showing a state prior to making a primary cleave of the nitride semiconductor laser device according to the second embodiment of the present invention shown in FIG. 21;

FIG. 27 is a plan view showing the device divided in a bar shape by the primary cleave;

FIG. 28 is a schematic view for describing the method for forming a trench by irradiating a YAG laser beam;

FIG. 29 is a plan view showing the state in which a trench has been formed by irradiating a YAG laser beam;

FIG. 30 is a cross-sectional view along the line 300-300 of FIG. 29;

FIG. 31 is a view for describing the shape of the trench formed by irradiating a YAG laser beam;

FIG. 32 is a plan view for describing the formation position of the trench and the device shape of an example and a comparative example;

FIG. 33 is a view for describing the shape of the trench according to the example; and

FIG. 34 is a view for describing the shape of the trench according to a comparative example.

### DESCRIPTION OF THE NUMERALS

1, 101 n-type GaN substrates (substrates)
2 n-type clad layer
3 active layer (light-emitting layer)
3a well layer
3b barrier layer
4 light-guide layer (nitride semiconductor layer)
5 p-type cap layer (nitride semiconductor layer)
6 p-type clad layer (nitride semiconductor layer)
7 contact layer (nitride semiconductor layer)
8 ridge (electric current channel)
9 p-side ohmic electrode
10 electric current blocking layer
11 p-side pad electrode
12 n-side electrode
20 notch (substrate-dividing notch)
30, 130 trenches
50 end surface of the resonator
60 side end surface
120 notch (substrate-dividing notch)

### BEST MODE FOR CARRYING OUT THE INVENTION

Embodiments of the present invention are described in detail below with reference to the drawings.

### First Embodiment

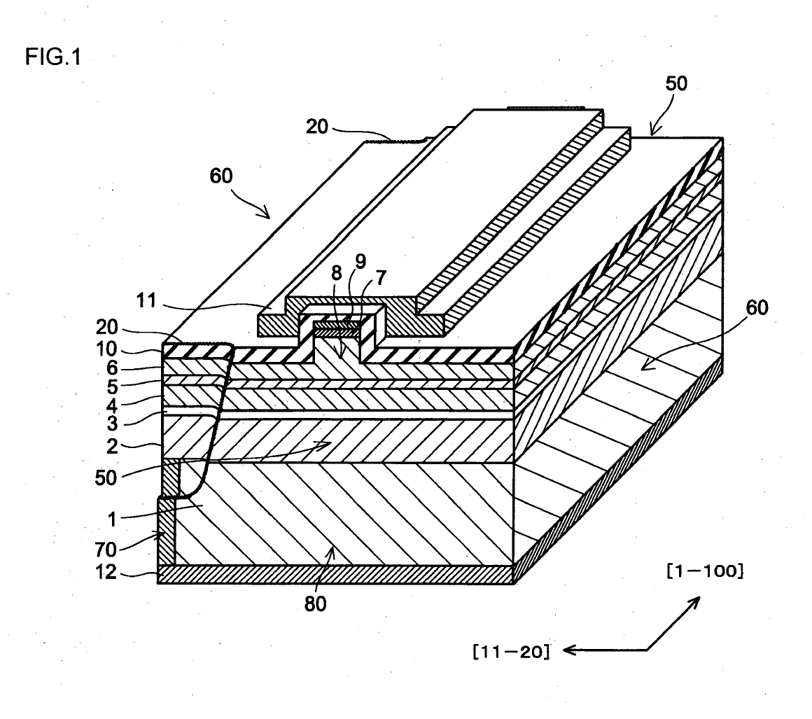

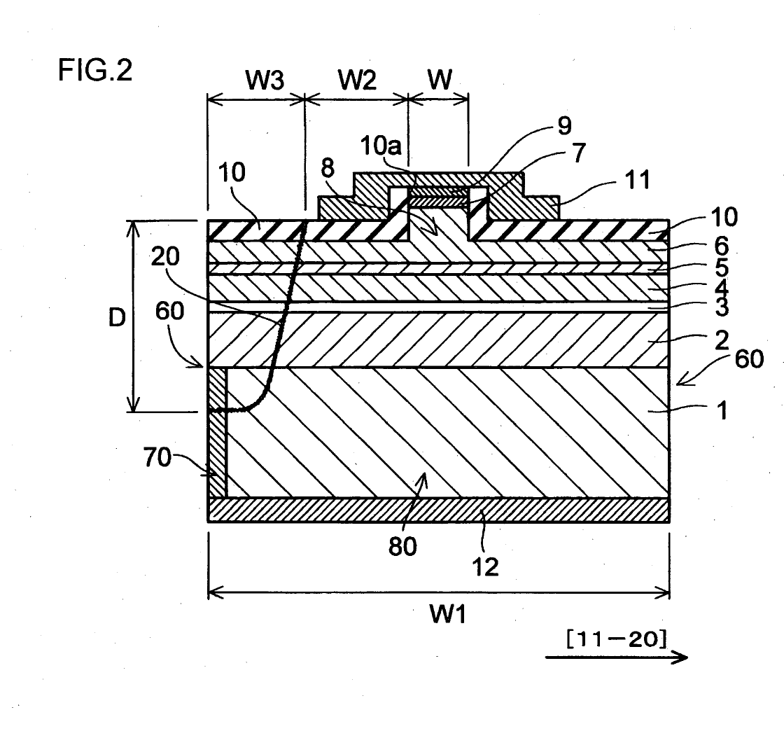

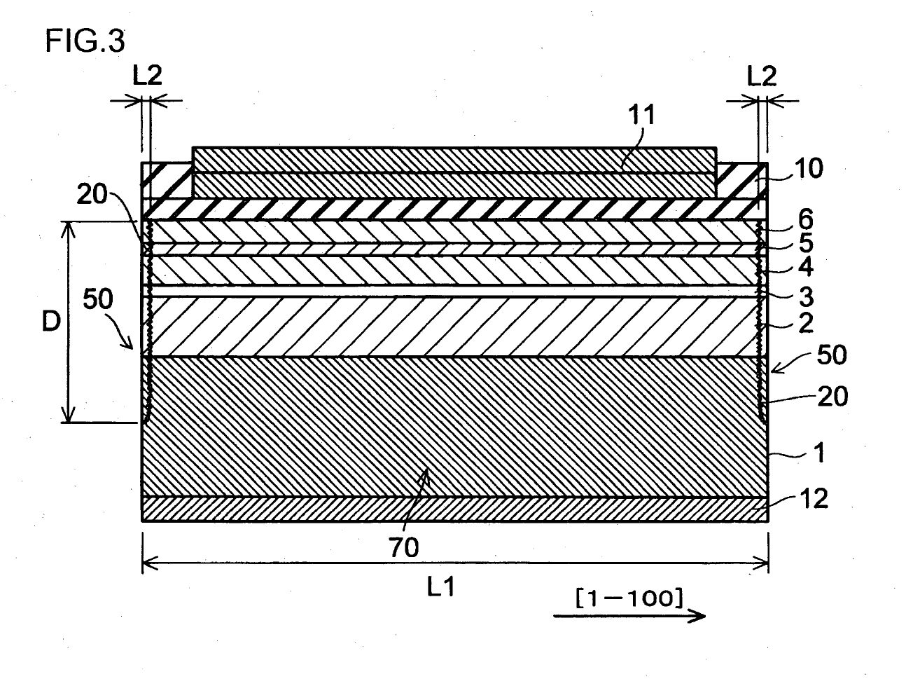

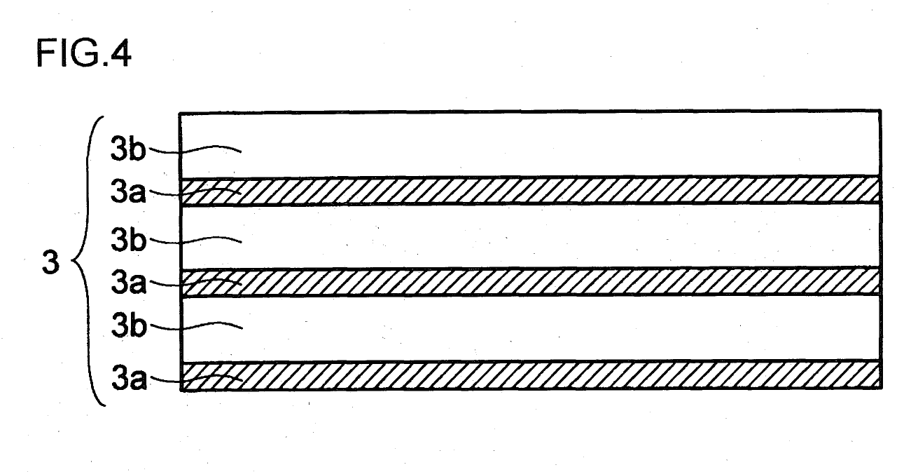

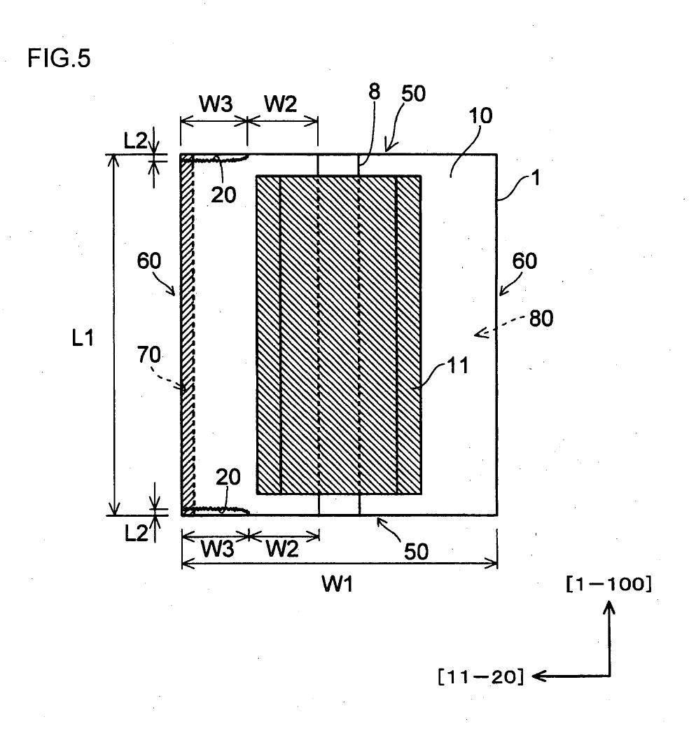

FIG. 1 is an overall perspective view of the nitride semiconductor laser device according to the first embodiment of the present invention as seen from the direction along which the electric current channel (ridge) extends. FIG. 2 is a front view of the nitride semiconductor laser device according to the first embodiment of the present invention shown in FIG. 1 as seen from the direction along which the electric current channel (ridge) extends. FIG. 3 is a side view of the nitride semiconductor laser device according to the first embodiment of the present invention shown in FIGS. 1 and 2 as seen from the direction in which the notch is formed. FIGS. 4 and 5 are views for describing the nitride semiconductor laser device according to the first embodiment of the present invention shown in FIG. 1. First, the structure of the nitride semiconductor laser device according to the first embodiment of the present invention will be described with reference to FIGS. 1 to 5.

In the nitride semiconductor laser device according to the first embodiment, an n-type clad layer 2 composed of an n-type AlGaN layer having a thickness of about 1.5 μm is formed on the upper surface of an n-type GaN substrate 1 having a thickness of about 100 μm, as shown in FIGS. 1 to 3. An active layer 3 is formed on the n-type clad layer 2. The active layer 3 has a multiple quantum well (MQW) structure in which three well layers 3a composed of an undoped InGaN layer having a thickness of about 3.2 nm and three barrier layers 3b composed of an undoped InGaN layer having a thickness of about 20 nm are layered in an alternating fashion, as shown in FIG. 4. The n-type GaN substrate 1 is an example of the “substrate” of the present invention, and the n-type clad layer 2 is an example of the “nitride semiconductor layer” of the present invention. The active layer 3 is an example of the “light-emitting layer” of the present invention.

A light-guide layer 4 composed of an undoped InGaN layer having a thickness of about 50 nm is formed on the active layer 3, as shown in FIGS. 1 and 2. A cap layer 5 composed of an undoped AlGaN layer having a thickness of about 20 nm is formed on the light-guide layer 4. A p-type clad layer 6 composed of a p-type AlGaN layer having a protrusion and a flat part other than the protrusion is formed on the cap layer 5. The thickness of the flat part of the p-type clad layer 6 is about 80 nm, and the height of the protrusion from the upper surface of the flat part is about 320 nm. A contact layer 7 composed of an undoped InGaN layer having a thickness of about 3 nm is formed on the protrusion of the p-type clad layer 6. A stripe-shaped (long narrow-shaped) ridge 8 having a width W (see FIG. 2) of about 1.5 μm is composed of the protrusion of the p-type clad layer 6 and the contact layer 7. The ridge 8 is formed so as to extend in the [1-100] direction, as shown in FIG. 5. The light-guide layer 4, the cap layer 5, the p-type clad layer 6, and the contact layer 7 are each an example of the “nitride semiconductor layer” of the present invention, and the ridge 8 is an example of the “electric current channel” of the present invention.

A p-side ohmic electrode 9 composed of a Pt layer (not shown) as a lower layer having a thickness of about 1 nm and a Pd layer (not shown) as an upper layer having a thickness of about 10 nm is formed in the shape of a stripe (long narrow shape) on the contact layer 7 constituting the ridge 8, as shown in FIGS. 1 and 2. An electric current blocking layer 10 having a thickness of about 200 nm and being composed of a SiO₂ layer is formed on the p-type clad layer 6 and on the side surface of the contact layer 7. The electric current blocking layer 10 is provided with an aperture 10a (see FIG. 2) that exposes the upper surface of the p-side ohmic electrode 9.

A p-side pad electrode 11 composed of an Au layer having a thickness of about 3 μm is formed on the upper surface of the electric current blocking layer 10 so as to cover the p-side ohmic electrode 9 exposed via the aperture 10a. An n-side electrode 12 composed of an Al layer (not shown) having a thickness of about 6 nm, a Pd layer (not shown) having a thickness of about 10 nm, and an Au layer (not shown) having a thickness of about 300 nm is formed on the lower surface (reverse surface) of the n-type GaN substrate 1 in sequence from the lower surface (reverse surface) of the n-type GaN substrate 1.

The nitride semiconductor laser device according to the first embodiment has a length L1 of about 300 μm to about 800 μm in the direction orthogonal to end surfaces 50 of the resonator ([1-100] direction), and a width W1 of about 200 μm to about 400 μm in the direction along the end surfaces 50 of the resonator ([11-20] direction), as shown in FIG. 5. Side end surfaces 60 orthogonal to the end surfaces 50 of the resonator are formed on the two sides of the ridge 8 of the nitride semiconductor laser device.

Here, in the first embodiment, a notch 20 for dividing the substrate is formed in the vicinity of the end surfaces 50 of the resonator in the upper surface of the n-type GaN substrate 1, as shown in FIGS. 1 to 3. The notch 20 is formed by irradiating a YAG laser beam from the upper surface of the electric current blocking layer 10 in the manufacturing method described below. In other words, the notch 20 is formed by causing the GaN constituting the n-type GaN substrate 1 to sublimate by irradiation using a YAG laser beam. The notch 20 is formed on at least one side end surface 60 so as to extend in the direction orthogonal to the ridge 8 ([11-20] direction), which is the electric current channel. The end parts of the notch 20 are formed in a region set at a predetermined distance W2 (about 50 μm to about 200 μm) from the side surface of the ridge 8, as shown in FIGS. 2 and 5. The notch 20 is an example of the “substrate-dividing notch” of the present invention.

In the first embodiment, the notch 20 is formed so that the length in the direction orthogonal to the ridge 8 ([11-20] direction) gradually increases from the bottom of the notch 20 to the upper surface of the n-type GaN substrate 1, as shown in FIG. 2. Specifically, in the end side (near the end parts of the ridge 8) of the notch 20, the depth of the notch 20 is formed so as to gradually increase toward the side end surface 60 (the side opposite from the ridge 8). A later-described high-displacement density region 70 that extends in the direction parallel to the ridge 8 ([1-100] direction) is provided to at least one of the side end surfaces 60 of the n-type GaN substrate 1, as shown in FIGS. 1, 2, and 5, and the notch 20 is formed so as to be transverse to the high-displacement density region 70. In other words, the notch 20 is formed to a length W3 of about 20 μm to about 50 μm in the [11-20] direction from the side end surface 60 to a region of a later-described low-displacement density region 80 adjacent to the high-displacement density region 70. The depth D (see FIG. 2) of the deepest part of the notch 20 is about 5 μm to about 80 μm, and is preferably about 20 μm to about 80 μm; and the length L2 of the width direction ([1-100] direction) of the notch 20 is about 5 μm.

In the first embodiment, the formation of very small longitudinal lines caused by the notch 20 can be reduced in the region below the region near the ridge 8 of the end surfaces 50 of the resonator when the n-type GaN substrate 1 is divided, because a notch 20 is formed in at least a part of the vicinity of the end surfaces 50 of the resonator in the upper surface of the n-type GaN substrate 1 by irradiating a YAG laser beam as described above and a notch 20 is not formed in the region near the ridge 8 by forming the end parts of the notch 20 in a region set at a predetermined distance W2 from the side surface of the ridge 8. In other words, the formation of very small longitudinal lines caused by the notch 20 can be reduced in the region about the periphery of the optical waveguide below the ridge 8 in the end surfaces 50 of the resonator. A notch 20 is formed in at least a portion of the region in the vicinity of the end surfaces 50 of the resonator in the upper surface of the n-type GaN substrate 1 by irradiating a YAG laser beam, whereby the stress applied to the device can be reduced when the n-type GaN substrate 1 is divided by applying stress to the device because the notch 20 is formed more deeply than the case in which the notch 20 is formed on the upper surface of the n-type GaN substrate 1 using a diamond needle.

Accordingly, the n-type GaN substrate 1 can be rectilinearly divided along a desired division line without making a division on a line inclined 60° from the desired division line or along another line, even when a hexagonal n-type GaN substrate 1 is used as the substrate. Therefore, the end surfaces 50 of the resonator can thereby be flatly formed and it is possible to reduce the occurrence of defects in which very small longitudinal lines are formed in the region about the periphery of the optical waveguide of the end surfaces 50 of the resonator due to dividing the n-type GaN substrate 1 at a line inclined 60° from the desired division line or along another line. The reflectivity of the end surfaces 50 of the resonator can be improved because the region about the periphery of the optical waveguide of the end surfaces 50 of the resonator can be formed into a mirror surface. As a result, a nitride semiconductor laser device having good light emission characteristics can be obtained. As described above, the formation of very small longitudinal lines is reduced in the region about the periphery of the optical waveguide of the end surfaces 50 of the resonator, whereby a reduction in yield during manufacture can be limited at the same time.

In the first embodiment, the end parts of the notch 20 are formed in a region set at a predetermined distance W2 from the ridge 8, whereby the region about the periphery of the ridge 8 can be prevented from being damaged by heat from the irradiation of YAG laser beam in the particular case that the notch 20 is formed by irradiating a YAG laser beam. Therefore, it is possible to limit the occurrence of defects in which light-emission characteristics are reduced due to the periphery of the ridge 8 being damaged by heat.

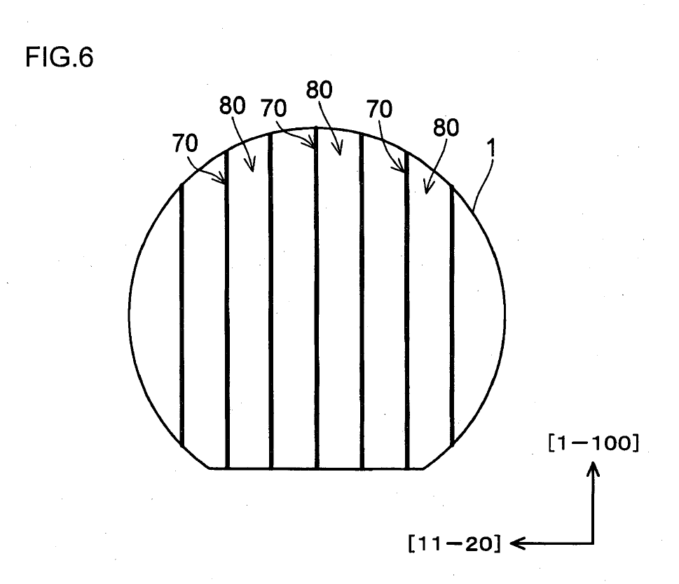

FIGS. 6 to 18 are diagrams describing the method for manufacturing a nitride semiconductor laser device according to the first embodiment of the present invention shown in FIG. 1. The method for manufacturing a nitride semiconductor laser device according to the first embodiment of the present invention will next be described with reference to FIGS. 1, 4, and 6 to 18.

First, an n-type GaN substrate 1 for growing nitride semiconductor layers is prepared. A high-displacement density region 70 having many more crystal defects than other regions, and a low-displacement density region 80 having fewer crystal defects than the high-displacement density region 70 are periodically arranged on the n-type GaN substrate 1 so as to extend in the [1-100] direction, as shown in FIG. 6. In other words, the high-displacement density region 70, which is a region of concentrated crystal defects, and the low-displacement density region 80, which is a region having very few crystal defects, coexist in the form of stripes. A (0001) plane is exposed on the upper surface of the low-displacement density region 80, and a (000-1) plane is exposed on the upper surface of the high-displacement density region 70. The crystal is therefore discontinuous at the boundary between the high-displacement density region 70 and the low-displacement density region 80.

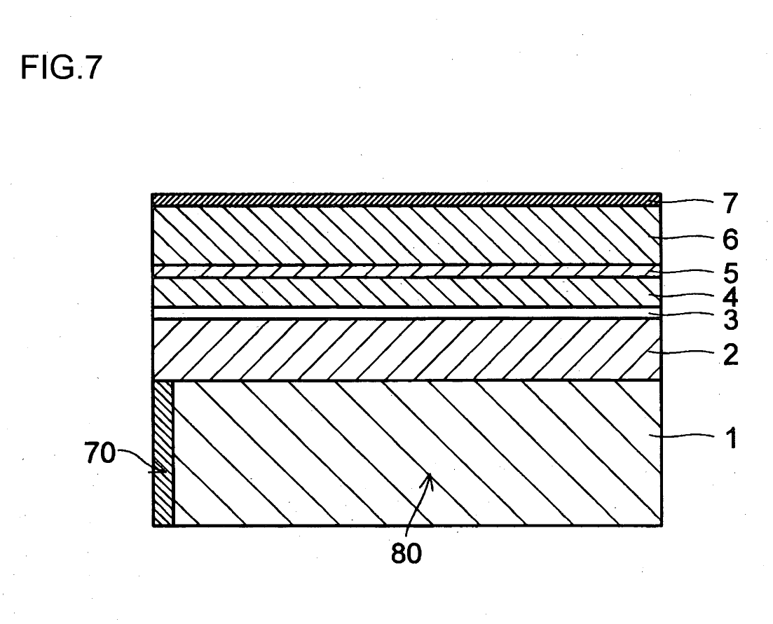

Next, an n-type clad layer 2 composed of an n-type AlGaN layer having a thickness of about 1.5 μm is formed on the upper surface of the n-type GaN substrate 1 using MOCVD (Metal Organic Chemical Vapor Deposition), as shown in FIG. 7, and an active layer 3 is formed on the n-type clad layer 2. Three well layers 3a composed of undoped InGaN layers having a thickness of about 3.5 nm and three barrier layers 3b composed of undoped InGaN layers having a thickness of about 20 nm are grown in alternating fashion when the active layer 3 is grown, as shown in FIG. 4. An active layer 3 having an MQW structure composed of three well layers 3a and three barrier layers 3b is thereby formed on the n-type clad layer 2. Next, sequentially grown on the active layer 3 are a light-guide layer 4 composed of an undoped InGaN layer having a thickness of about 50 nm and a cap layer 5 composed of an undoped AlGaN layer having a thickness of about 20 nm, as shown in FIG. 7. Thereafter sequentially grown on the cap layer 5 are a p-type clad layer 6 composed of a p-type AlGaN layer having a thickness of about 400 nm and a contact layer 7 composed of an undoped InGaN layer having a thickness of about 3 nm.

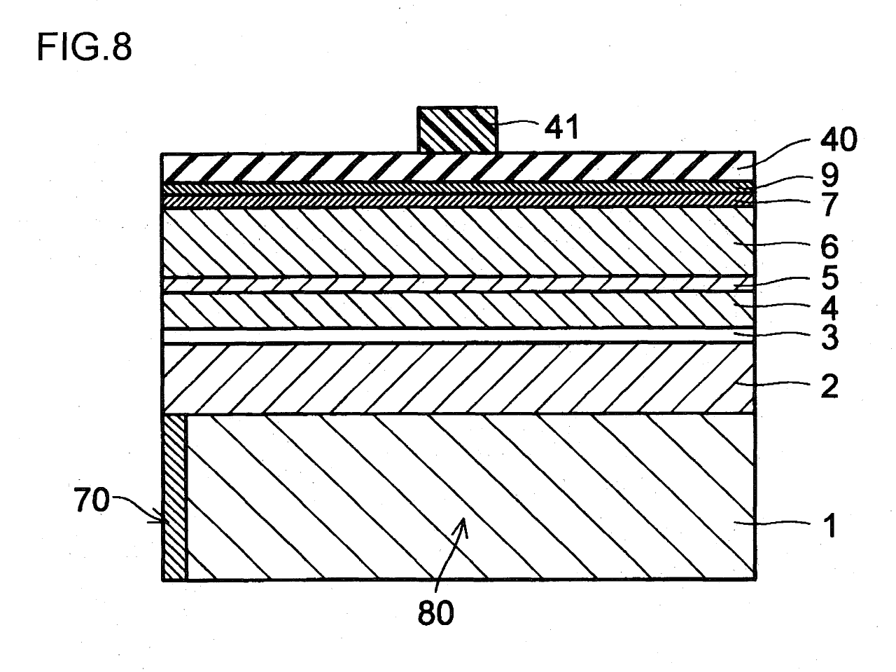

Next, a p-side ohmic electrode 9 composed of a Pt layer (not shown) as a lower layer having a thickness of about 1 nm and a Pd layer (not shown) as an upper layer having a thickness of about 10 nm are formed on the contact layer 7 using electron beam vapor deposition, as shown in FIG. 8. A SiO₂ layer 40 having a thickness of about 240 nm is then formed on the p-side ohmic electrode 9 using plasma CVD. A stripe-shaped (long narrow-shaped) resist 41 extending in the [1-100] direction and having a width of about 1.5 μm is formed on the SiO₂ layer 40 using photolithography.

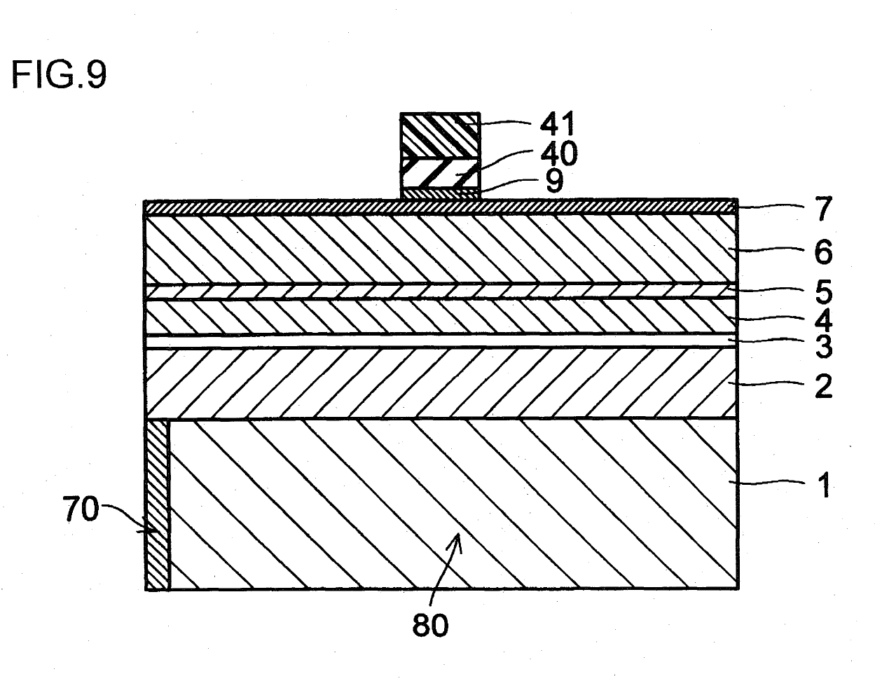

Next, a SiO₂ layer 40 and a p-side ohmic electrode 9 are etched by RIE (Reactive Ion Etching) using the resist 41 as a mask with the aid of CF₄ gas, as shown in FIG. 9. The resist 41 is then removed.

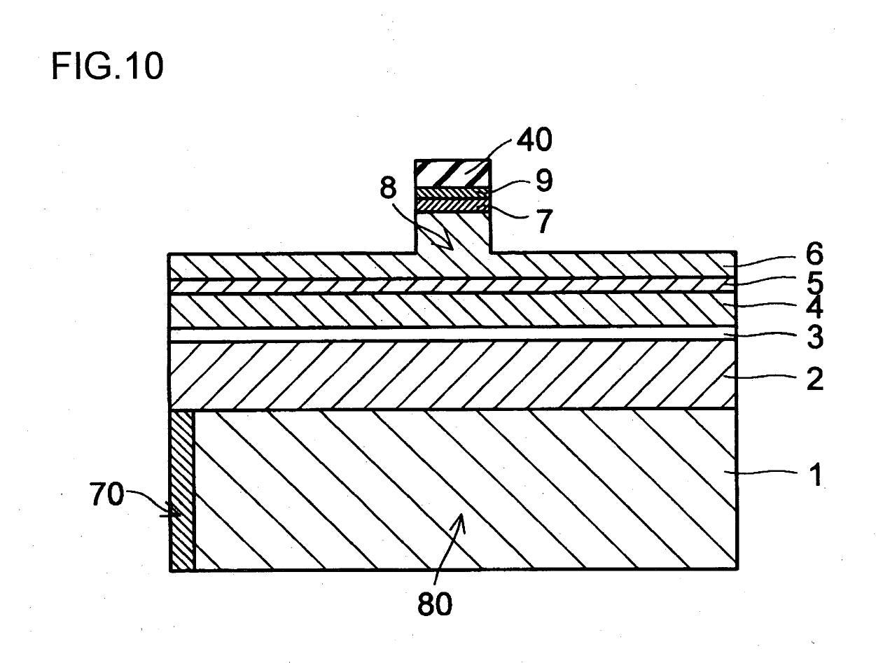

Next, a stripe-shaped (long narrow-shaped) ridge 8 extending in the [1-100] direction and being composed of the contact layer 7 and a protrusion of the p-type clad layer 6 is formed by etching from the upper surface of the contact layer 7 to a depth midway through the p-type clad layer 6 (a depth of about 320 nm from the upper surface of the p-type clad layer 6) using the SiO₂ layer 40 as a mask by RIE with the aid of chloride gas, as shown in FIG. 10. The ridge 8 is formed so as to be positioned above the upper surface of the low-displacement density region 80 of the n-type GaN substrate 1. The SiO₂ layer 40 is then removed.

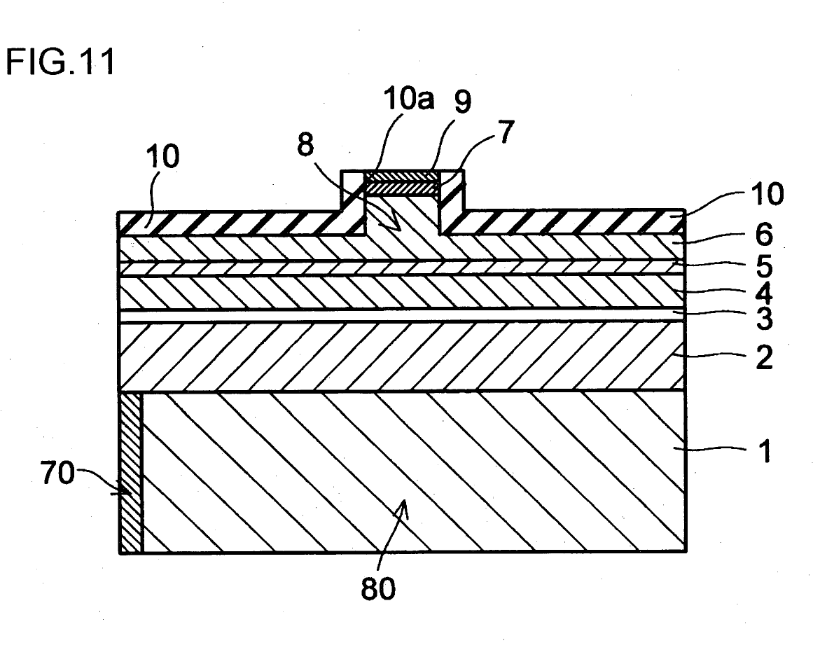

A SiO₂ layer (not shown) having a thickness of about 200 nm is subsequently formed using plasma CVD so as to cover the entire surface, and the portion position above the p-side ohmic electrode 9 of the SiO₂ layer (not shown) is thereafter removed by photolithography and RIE with the aid of CF₄ gas. An electric current blocking layer 10 composed of a SiO₂ layer and having an aperture 10a is thereby formed, as shown in FIG. 11.

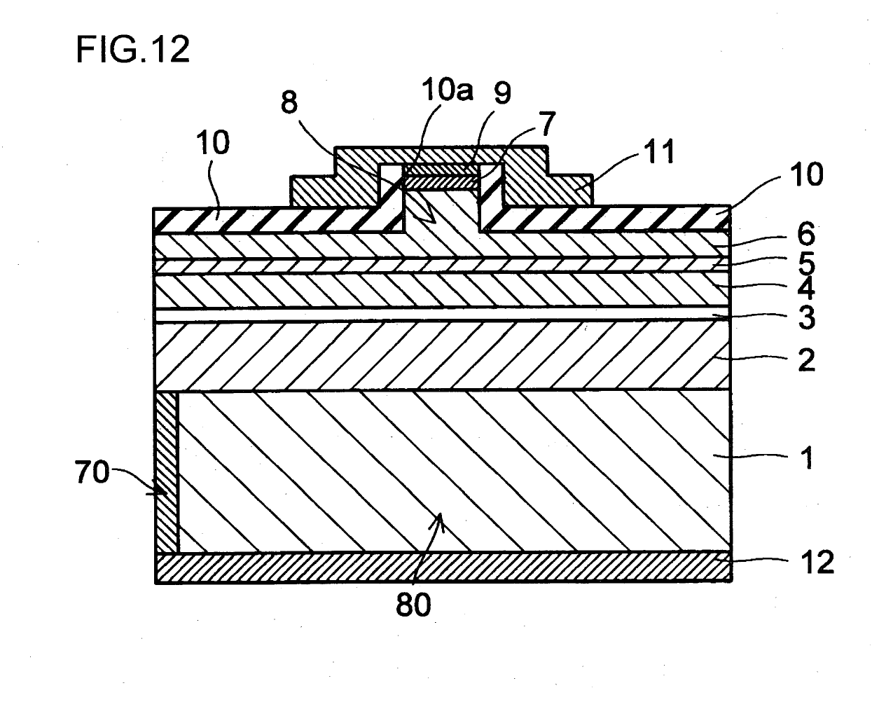

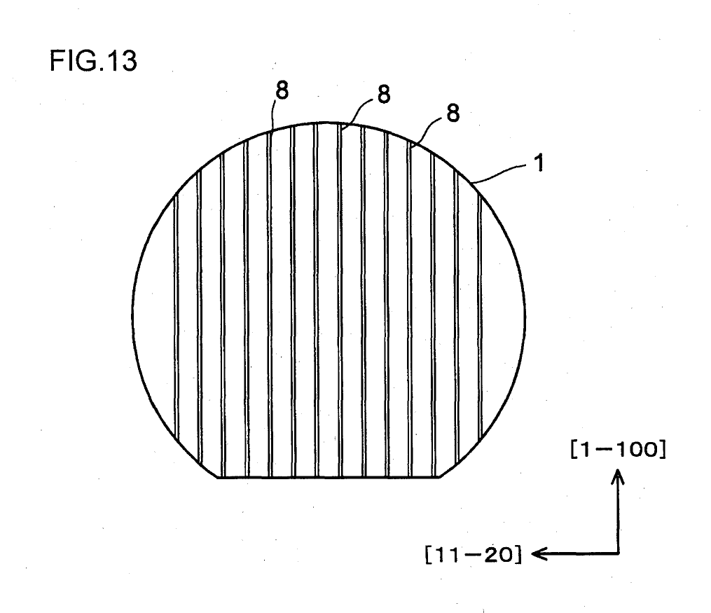

Next, a p-side pad electrode 11 composed of an Au layer having a thickness of about 3 μm is formed on the electric current blocking layer 10 by resistance heating vapor deposition so as to cover the exposed p-side ohmic electrode 9, as shown in FIG. 12. The lower surface (reverse surface) of the n-type GaN substrate 1 is subsequently polished until the thickness of the n-type GaN substrate 1 reaches about 100 μm. An n-side electrode 12 composed of an Al layer (not shown) having a thickness of about 6 nm, a Pd layer (not shown) having a thickness of about 10 nm, and a Au layer (not shown) having a thickness of about 300 nm is thereafter formed on the lower surface (reverse surface) of the n-type GaN substrate 1 in sequence from the lower surface (reverse surface) of the n-type GaN substrate 1. FIG. 13 shows a plan view of the state shown in FIG. 12.

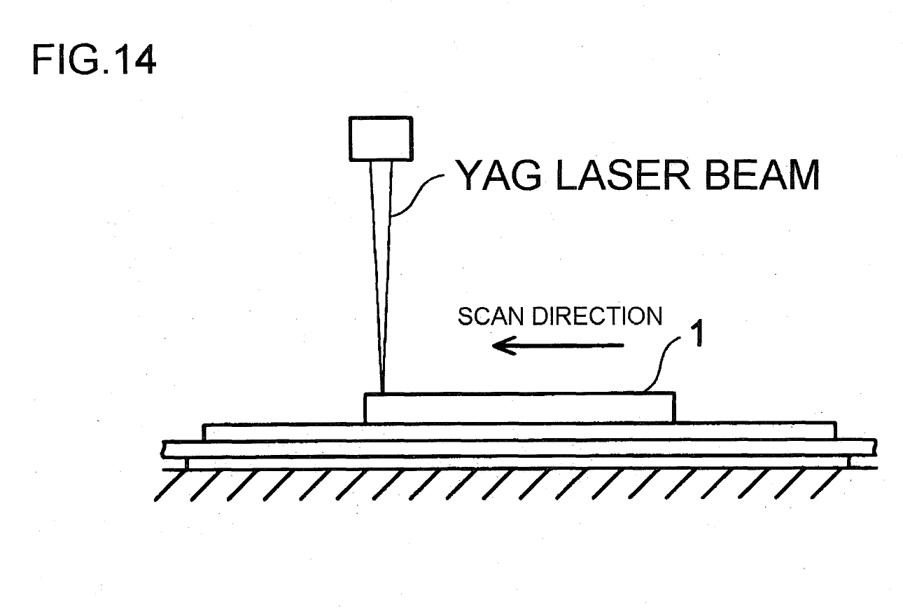

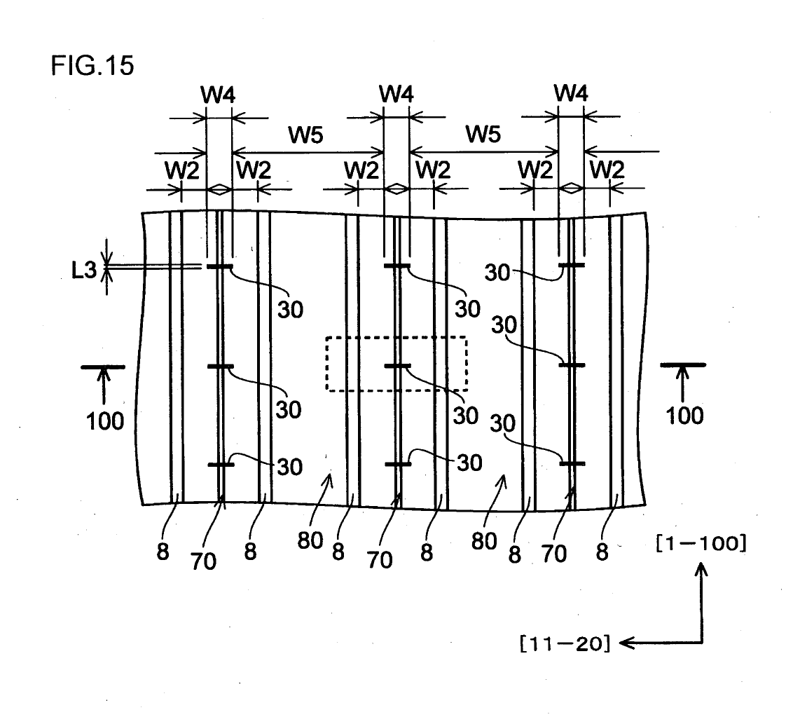

Next, the device is divided (cleaved) into a bar shape by making a primary cleave from the state shown in FIG. 13. Specifically, a YAG laser beam is irradiated from the upper surface (the side on which nitride semiconductor layers are formed) of the n-type GaN substrate 1, and the n-type GaN substrate 1 is moved in the [11-20] direction, as shown in FIG. 14, whereby a trench 30 extending in the direction orthogonal to the ridge 8 ([11-20] direction) is formed on the upper surface of the n-type GaN substrate 1, as shown in FIG. 15.

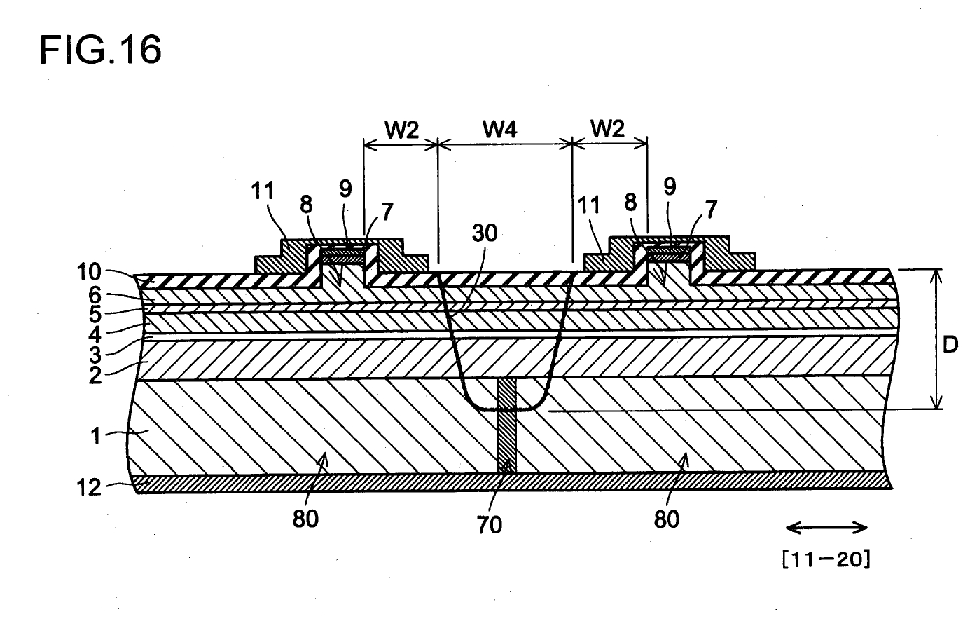

Here, in the first embodiment, the trench 30 is formed so as to transverse the high-displacement density region 70 provided between ridges 8, as shown in FIG. 15. In such a case, the end parts of the trench 30 are formed so as to be positioned in a region set at a predetermined distance W2 (about 50 μm to about 200 μm) from the side surface of the ridge 8. Specifically, the trench 30 is intermittently formed in the shape of a wave-shaped line in which the distance between trenches is W5 (μm) by intermittently irradiating a YAG laser beam, whereby the trench 30 is formed so as to transverse the high-displacement density region 70 in a region between ridges 8 in which the high-displacement density region 70 is provided. The trench 30 is formed so that the length L3 in the width direction is about 10 μm, the depth D of the deepest part is about 5 μm to about 80 μm, preferably about 20 μm to about 80 μm, and the length W4 of the aperture end of the trench 30 is about 40 μm to about 100 μm, as shown in FIG. 16. The trench 30 may be formed between ridges 8 where the high-displacement density region 70 is not provided.

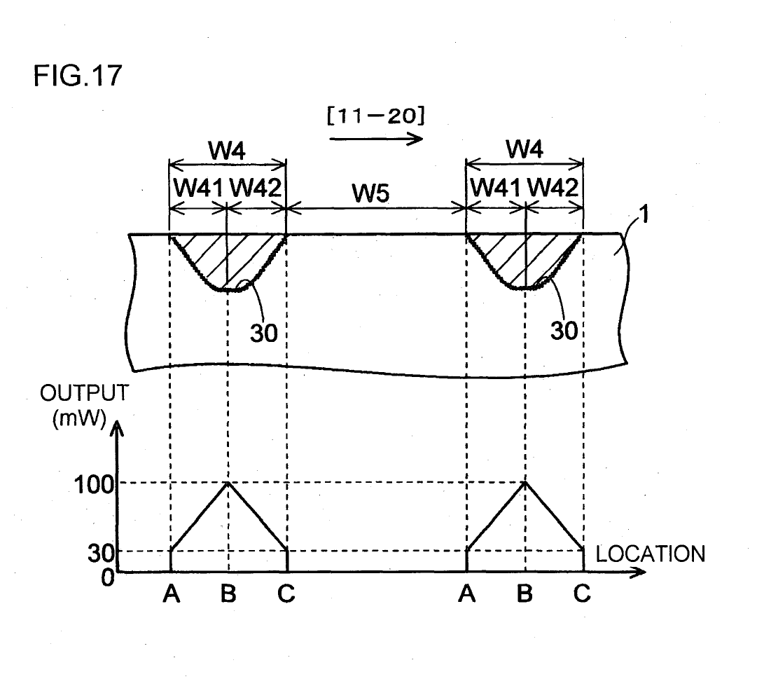

In the first embodiment, the length of the trench 30 in the direction orthogonal to the ridge 8 ([11-20] direction) is formed so as to gradually increase from the bottom of the notch 20 toward the upper surface of the n-type GaN substrate 1. Specifically, the YAG laser beam is irradiated onto the upper surface of the n-type GaN substrate 1 while the output of the YAG laser beam is gradually increased to between about 30 mW to about 100 mW from the starting position A (one end part of the trench 30) where the YAG laser beam is irradiated to a position B apart from the position A at a distance W41, as shown in FIG. 17. Also, the YAG laser beam is irradiated onto the upper surface of the n-type GaN substrate 1 while the output of the YAG laser beam is gradually reduced to between about 100 mW to about 30 mW from the position B to an end position C (other end part of the trench 30) apart from the position B at distance W42 where the YAG laser beam is irradiated. The two end parts of the trench 30 are formed so that the depth of the trench 30 gradually increases from the end parts to the center. In other words, a trench 30 having a boat shape is formed. The trench 30 is asymmetrically formed from the center in the [11-20] direction. The conditions (output, frequency, focal position, substrate movement speed, and the like) for irradiating a YAG laser beam can be arbitrarily modified in order to obtain a desired trench shape.

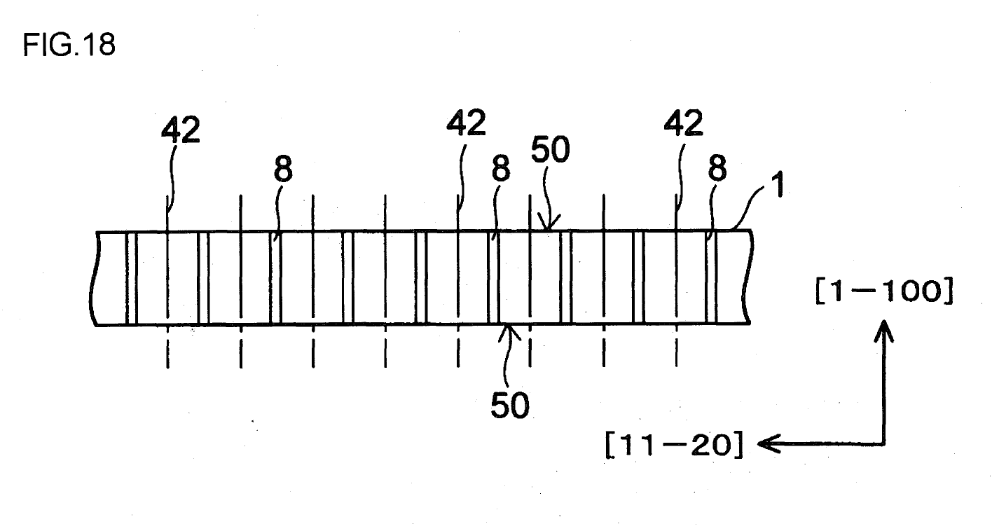

Stress is subsequently applied to the device and the n-type GaN substrate 1 is divided (cleaved) along the trench 30 by pressing the blade of a breaker from the lower surface (the surface on the side opposite from the surface in which the trench 30 is formed) of the n-type GaN substrate 1. The n-type GaN substrate 1 is thereby divided in a bar shape, as shown in FIG. 18. End surfaces 50 of the resonator are formed on the cleaved surfaces of the device thus divided in a bar shape. The end surfaces 50 of the resonator are composed of a (-1100) plane and a (1-100) plane parallel to the [11-20] direction. The n-type GaN substrate 1 is divided along the trench 30, whereby the notch 20 (see FIGS. 1 to 3) described above is formed in the vicinity of the end surfaces 50 of the resonator.

Lastly, the device is divided (secondary cleave) at an alternate long and short dash line 42, which extends in the [1-100] direction, between mutually adjacent ridges 8 from the state shown in FIG. 18 to thereby form a chip shape. A side end surface 60 orthogonal to the end surfaces 50 of the resonator is formed by the secondary cleave. In this manner, a nitride semiconductor laser device according to the first embodiment such as that shown in FIG. 1 is formed.

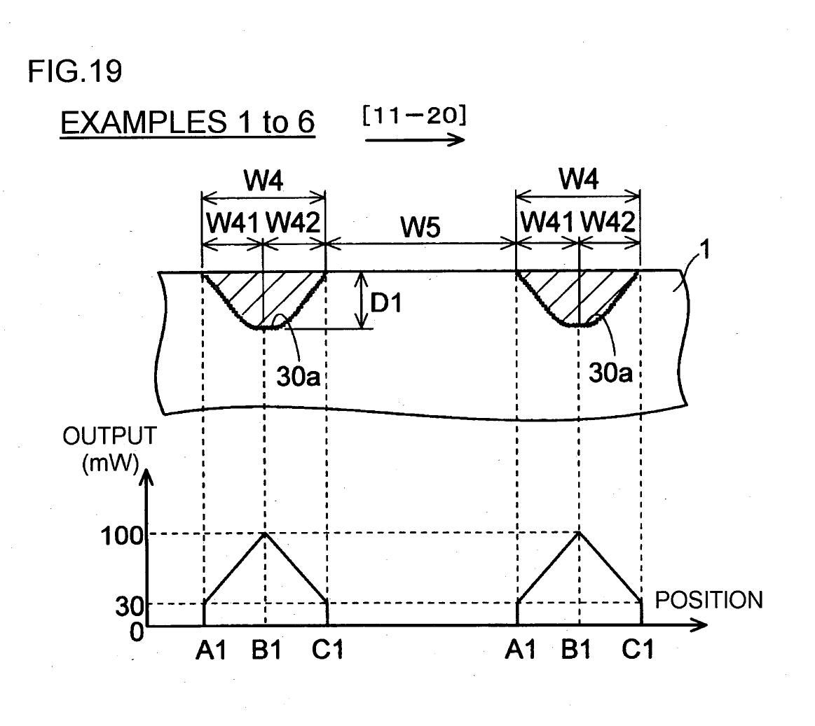

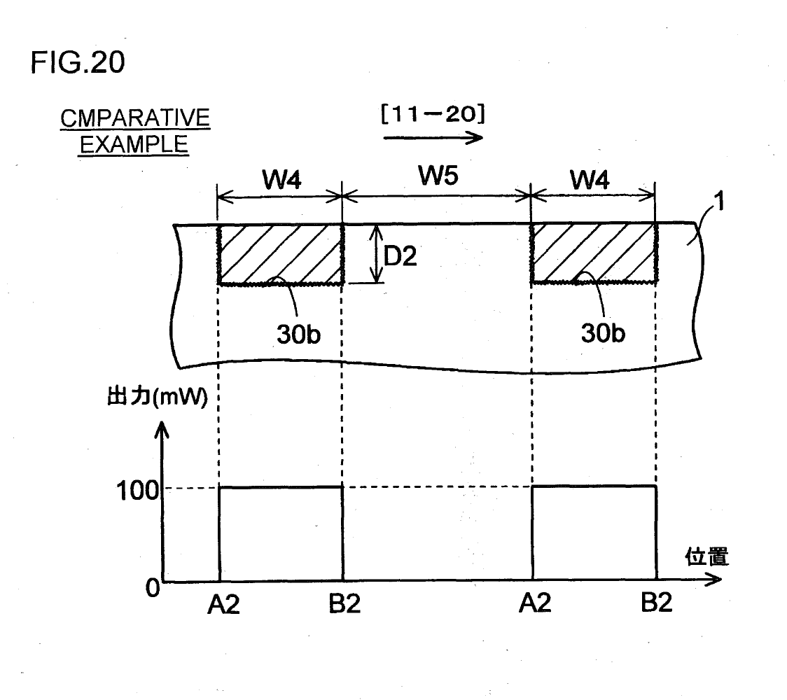

Next, an experiment carried out in order to confirm the effects of the embodiment described above will be explained. In the experiment, the yield ratio was measured for cases in which the trench shape was modified in various ways in order to confirm the effect of the trench shape on the yield at the time of the primary cleave of the nitride semiconductor laser device. FIG. 19 is a diagram describing the trench shapes according to examples 1 to 6. FIG. 20 is a diagram describing the trench shape according to a comparative example.

The trench shape according to examples 1 to 6 is a boat shape in a similar manner to the embodiment described above, as shown in FIG. 19. Specifically, the YAG laser beam was irradiated onto the upper surface of the n-type GaN substrate 1 while the output of the YAG laser beam was gradually increased to between about 30 mW to about 100 mW from the starting position A1 (one end part of a trench 30a) where the YAG laser light was irradiated to the position B1 apart from the position A1 at a distance W41. The YAG laser beam was irradiated onto the upper surface of the n-type GaN substrate 1 while the output of the YAG laser beam was gradually reduced to between about 100 mW to about 30 mW from the position B1 to an end position C1 (other end part of the trench 30a) apart from the position B1 at a distance w42 where the YAG laser beam was irradiated. The two end parts of the trench 30a were thereby formed so that the depth of the trench 30 was gradually increased from the end parts toward the center. The trench 30a was formed in an intermittent wave-shaped line in which the distance between trenches was W5 (μm). In examples 1 to 6, the length W4 (=W41+W42) of the trench 30a and the distance W5 between the trenches were varied.

The trench shape in the comparative example was formed so as to be rectangular shape, as shown in FIG. 20. In other words, a YAG laser beam was irradiated onto the upper surface of the n-type GaN substrate 1 at a constant output of about 100 mW from a starting position A2 (one end of a trench 30b) where the YAG laser beam is irradiated to an end point B2 (other end of the trench 30b), whereby the length W4 of the trench 30b in the [11-20] direction was formed so that the bottom of the trench 30b and the aperture end of the trench 30b had substantially the same length W4. The trench 30b was formed in an intermittent wave-shaped line in which the distance between trenches was W5 (μm)

The examples 1 to 6 and the comparative example were each carried out using the same conditions, except for the trench shape and the distance W5 between trenches. In other words, the same nitride semiconductor laser device as in the embodiment described above was used as the semiconductor laser devices, and the depths D1 and D2 of the deepest parts of the trenches 30a and 30b were both set to about 40 μm. The distances between ridges 8 were each set to about 200 μm. The trenches 30a and 30b formed between ridges 8 where the high-displacement density region 70 was formed were configured so as to transverse the high-displacement density region. The conditions for irradiating the YAG laser beam were the same for examples 1 to 6 and the comparative example, i.e., a frequency of 50 kHz, a substrate movement speed of 5 mm/s, and a focal position of −20 μm. In other words, the focal point was set to meet at a position 20 μm above the surface (the direction opposite from the n-type GaN substrate 1) of the electric current blocking layer 10. A laser scriber WSF4000 manufactured by Opto Systems was used as the laser scribe apparatus for forming the trenches 30a and 30b.

The blade of a breaker was pressed against the devices according to examples 1 to 6 and the comparative example formed in the manner described above from the lower surface (the surface in which the trenches 30a and 30b were not formed) of the n-type GaN substrate 1, and the n-type GaN substrate 1 was divided (cleaved) in bar shapes along the trenches 30a and 30b. The number of defective divisions (defective cleaves) at the time of division was counted and the yield ratio (%) of the primary cleave was calculated. The reference for determining a defective division (defective cleave) was based on whether very small longitudinal lines or the like other than the very small longitudinal lines caused by the trenches 30a and 30b were present in the end surfaces 50 (cleave surfaces) of the resonator. In other words, a defective division was determined in the case that very small longitudinal lines caused by factors other than the trenches were present in the end surfaces 50 of the resonator. The number of units counted for the examples 1 to 6 and the comparative example was 250, and the calculation of the yield ratio (%) was carried out by dividing the number of defective divisions by the number of units counted. The results are shown in TABLE 1.

TABLE 1

| | Comparative | Example | Example | Example | Example | Example | Example |
|---|---|---|---|---|---|---|---|
| | example | 1 | 2 | 3 | 4 | 5 | 6 |
| Trench shape | Rectangular | Boat shape | | | | | |
| Trench length (μm) | 80 | 80 | 80 | 50 | 50 | 60 | 100 |
| W4(=W41 + W42) | | | | | | | |
| W41 | — | 40 | 40 | 25 | 25 | 30 | 50 |
| W42 | — | 40 | 40 | 25 | 25 | 30 | 50 |
| Distance between | 320 | 320 | 120 | 350 | 150 | 340 | 100 |
| trenches (μm) W5 | | | | | | | |
| Yield ratio (%) | 77.6 | 100 | 100 | 100 | 100 | 100 | 100 |

As a result of comparing example 1 and the comparative example in which the trench length W4 and the distance W5 between trenches are equal as shown in TABLE 1, it is apparent that example 1 in which the trench shape is a boat shape has a higher yield ratio than the comparative example in which the trench shape is rectangular. Specifically, the yield ratio was 77.6% in the comparative example in which the trench shape was formed into a rectangular shape. However, in contrast, the yield ratio was 100% in example 1 in which the trench shape was formed into a boat shape and the yield ratio was higher than that in the comparative example. When the trench shape is formed in a boat shape, it is apparent that the yield ratio is greater than that of the comparative example in which the trench shape was formed into a rectangular shape, even in cases in which the trench length W4 and the distance W5 between trenches were varied. Specifically, the yield ratios for examples 2 to 6 in which the trench length W4 and the distance W5 between trenches were varied were 100% in the same manner as example 1. It was confirmed that the yield ratio is improved by forming the trench shape into a boat shape in comparison with the case in which the trench shape is formed into a rectangular shape. In other words, it was confirmed that the yield ratio is improved by forming the trench 30 so that the length of the trench 30 in the [11-20] direction gradually increases from the bottom of the trench 30 toward the upper surface of the n-type GaN substrate 1. It was also confirmed that the region about the periphery of the optical waveguide of the end surfaces 50 of the resonator can be readily formed into a mirror surface by improving the yield ratio because the trench 30 is not formed in a region near the ridge 8.

In the method for manufacturing a nitride semiconductor laser device according to the first embodiment, since the trench 30 is not formed in the region near the ridge 8 by forming the trench 30 extending in the direction orthogonal to the ridge 8 ([11-20] direction) on the upper surface of the n-type GaN substrate 1 by irradiating a YAG laser beam onto the upper surface of the electric current blocking layer 10, and by forming the end parts of the trench 30 in a region set at a predetermined distance W2 from the ridge 8, as described above, it is possible to reduce the formation of very small longitudinal lines caused by the trench 30 in the region below the region near the ridge 8 of the end surfaces 50 of the resonator when the n-type GaN substrate 1 is divided using the trench 30 as a starting point. In other words, the formation of very small longitudinal lines caused by the trench 30 can be reduced in the region about the periphery of the optical waveguide below the ridge 8 in the end surfaces 50 of the resonator. Since the trench 30 is formed extending in the direction orthogonal to the ridge 8 ([11-20] direction) on the upper surface of the n-type GaN substrate 1 by irradiating a YAG laser beam onto the upper surface of the electric current blocking layer 10, the trench 30 can be more deeply formed in comparison with the case in which the trench 30 is formed on the upper surface of the n-type GaN substrate 1 using a diamond needle, and it is also possible to reduce the stress applied to the device when the n-type GaN substrate 1 is divided by applying stress to the device.

Accordingly, since the n-type GaN substrate 1 can be rectilinearly divided along a desired division line without making a division at a line inclined 60° from the desired division line or at another line even when a hexagonal n-type GaN substrate 1 is used as a substrate, the end surfaces 50 of the resonator can be flatly formed and it is possible to reduce the occurrence of defects in which very small longitudinal lines or the like are formed in the region about the periphery of the optical waveguide of the end surfaces 50 of the resonator due to the n-type GaN substrate 1 being divided at a line inclined 60° from the desired division line or at another line. The reflectivity of the end surfaces 50 of the resonator can thereby be improved because the region about the periphery of the optical waveguide of the end surfaces 50 of the resonator can be formed into a mirror surface. As a result, a nitride semiconductor laser device having good light emission characteristics can be manufactured. As described above, it is also possible to limit a reduction in yield at the same time during manufacture by reducing the formation of very small longitudinal lines in the region about the periphery of the optical waveguide of the end surfaces 50 of the resonator.

In the first embodiment, the end parts of the trench 30 are formed in a region set at a predetermined distance W2 from the ridge 8, whereby the region about the periphery of the ridge 8 can be prevented from being damaged by heat from the irradiation of YAG laser beam in the particular case that the trench 30 is formed by irradiating a YAG laser beam. Therefore, it is possible to limit the occurrence of defects in which light-emission characteristics are reduced due to the periphery of the ridge 8 being damaged by heat.

In the first embodiment, the portions acting as the ridge 8 after the n-type GaN substrate 1 has been divided are moved in mutually separating directions when the n-type GaN substrate 1 is divided by forming the trench 30 on the upper surface of the n-type GaN substrate 1 and using the trench 30 as a starting point. Therefore, defects in which the portions acting as the ridge 8 after the n-type GaN substrate 1 has been divided interfere with each other and the ridge 8 deforms do not occur in contrast to the case in which the trench 30 is formed on the lower surface of the n-type GaN substrate 1. For this reason, it is possible to reduce the occurrence of defects in which the light emission characteristics are reduced due deformation of the end parts of the ridge 8 after the n-type GaN substrate 1 has been divided.

In the first embodiment, the length of the trench 30 in the direction orthogonal to the ridge 8 ([11-20] direction) is formed so as to gradually increase from the bottom of the trench 30 toward the upper surface of the n-type GaN substrate 1, whereby the n-type GaN substrate 1 can be readily divided using the trench 30 as a starting point. Therefore, the n-type GaN substrate 1 can be rectilinearly divided in a simple manner along a desired division line even when the end parts of the trench 30 are formed in a region set at a predetermined distance W2 from the ridge 8. The reflectivity of the end surfaces 50 of the resonator can thereby be readily improved because the region about the periphery of the optical waveguide of the end surfaces 50 of the resonator can be formed into a mirror surface in a simple manner.

In the first embodiment, the crystallographic axes of the n-type GaN substrate 1 and the plurality of nitride semiconductor layers formed on the n-type GaN substrate 1 can be made to match by using the n-type GaN substrate 1 as a substrate. Therefore, the n-type GaN substrate 1 and the nitride semiconductor layers can be divided at a readily dividable uniform crystallographic axis. The nitride semiconductor laser device can thereby be rectilinearly divided in a simple manner along a desired division line and the region about the periphery of the optical waveguide of the end surfaces 50 of the resonator can be formed into a mirror surface in a simpler manner. As a result, the reflectivity of the end surfaces 50 of the resonator can be more readily improved.

In the first embodiment, the trench 30 is formed so as to transverse the high-displacement density region 70 by irradiating a YAG laser beam, whereby the n-type GaN substrate 1 can be rectilinearly divided along a desired division line in a simple manner even in the case that a n-type GaN substrate 1 is used as a substrate in which a high-displacement density region 70 and a low-displacement density region 80 are periodically arranged. In other words, it is difficult to make a rectilinear cleave because the crystal is discontinuous at the boundary between the high-displacement density region 70 and the low-displacement density region 80. However, even when the crystal is discontinuous at the boundary between the high-displacement density region 70 and the low-displacement density region 80, the n-type GaN substrate 1 can be rectilinearly cleaved (divided) in a simple manner by dividing the n-type GaN substrate 1 along the trench 30 because the trench 30 is formed so as to transverse the high-displacement density region 70, whereby the trench is also formed at the boundary between the high-displacement density region 70 and the low-displacement density region 80.

### Second Embodiment

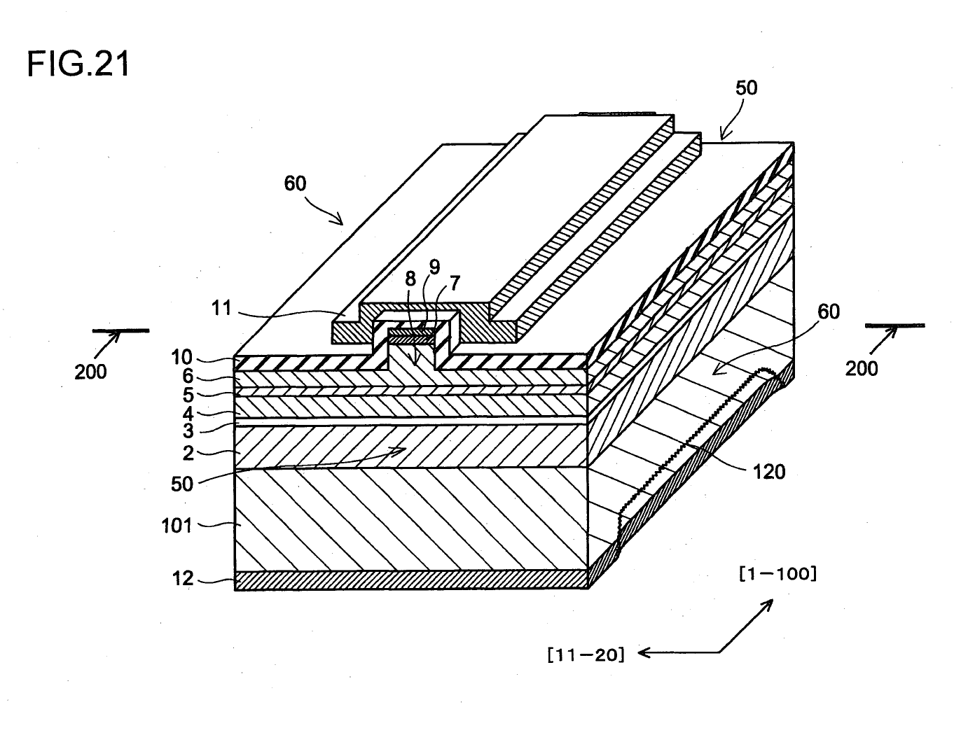

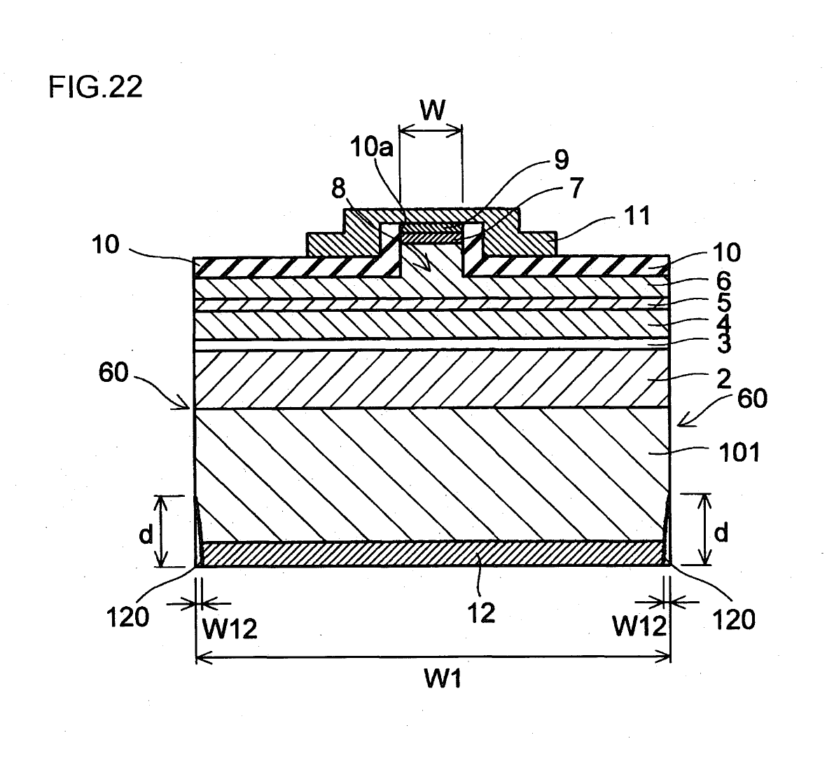

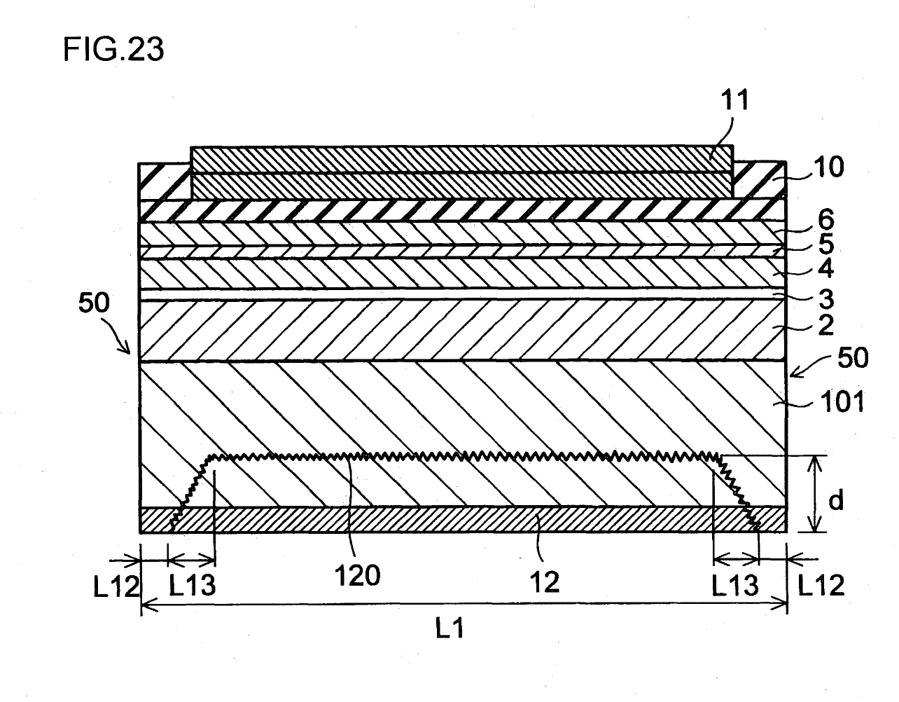

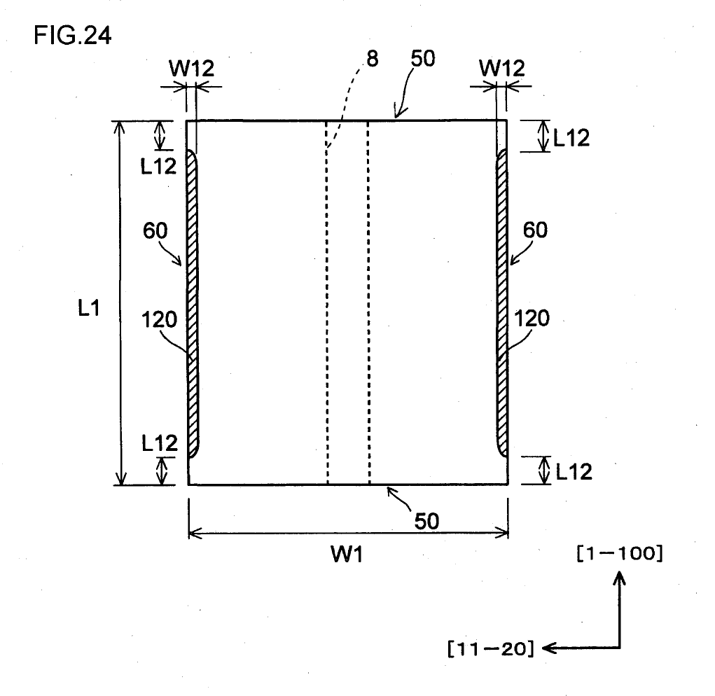

FIG. 21 is an overall perspective view of the nitride semiconductor laser device according to the second embodiment of the present invention as seen from the direction along which the electric current channel (ridge) extends. FIG. 22 is a cross-sectional view along the line 200-200 of FIG. 21. FIG. 23 is a side view of the nitride semiconductor laser device according to the second embodiment of the present invention shown in FIG. 21. FIG. 24 is a plan view of the nitride semiconductor laser device according to the second embodiment of the present invention shown as seen from the reverse surface. Next, the structure of the nitride semiconductor laser device according to the second embodiment will be described with reference to FIGS. 4 and 21 to 24.

In the nitride semiconductor laser device according to the second embodiment, the same layers (2 to 7 and 9 to 11) as the first example described above are sequentially layered on the upper surface of a n-type GaN substrate 101, as shown in FIGS. 21 to 23. Specifically, sequentially formed on the (0001) plane of an n-type GaN substrate 101 having a thickness of about 100 μm are an n-type clad layer 2 composed of an n-type AlGaN layer having a thickness of about 1.5 μm, an active layer 3, a light-guide layer 4 composed of an undoped InGaN layer having a thickness of about 50 nm, and a cap layer 5 composed of an undoped AlGaN layer having a thickness of about 20 nm. The active layer 3 has a multiple quantum well (MQW) structure in which three well layers 3a composed of an undoped InGaN layer having a thickness of about 3.2 nm and three barrier layers 3b composed of an undoped InGaN layer having a thickness of about 20 nm are layered in an alternating fashion, as shown in FIG. 4. The n-type GaN substrate 101 is an example of the “substrate” of the present invention.

A p-type clad layer 6 composed of a p-type AlGaN layer having a protrusion and a flat part in addition to the protrusion is formed on the cap layer 5, as shown in FIGS. 21 and 22. The thickness of the flat part of the p-type clad layer 6 is about 80 nm, and the height of the protrusion from the upper surface of the flat part is about 320 nm. A contact layer 7 composed of an undoped InGaN layer having a thickness of about 3 nm is formed on the protrusion of the p-type clad layer 6. A stripe-shaped (long narrow-shaped) ridge 8 having a width W of about 1.5 μm is composed of the protrusion of the p-type clad layer 6 and the contact layer 7. The ridge 8 is formed so as to extend in the [1-100] direction, as shown in FIG. 24.

A p-side ohmic electrode 9 composed of a Pt layer (not shown) having a thickness of about 1 nm and a Pd layer (not shown) having a thickness of about 10 nm is formed in the shape of a stripe (long narrow shape) on the contact layer 7 constituting the ridge 8, as shown in FIGS. 21 and 22. An electric current blocking layer 10 having a thickness of about 200 nm and being composed of a SiO₂ layer is formed on the p-type clad layer 6 and the side surface of the contact layer 7. The electric current blocking layer 10 is provided with an aperture 10a (see FIG. 2) that exposes the upper surface of the p-side ohmic electrode 9.

A p-side pad electrode 11 composed of an Au layer having a thickness of about 3 μm is formed on the upper surface of the electric current blocking layer 10 so as to cover the p-side ohmic electrode 9 exposed via the aperture 10a. An n-side electrode 12 composed of an Al layer (not shown) having a thickness of about 6 nm, a Pd layer (not shown) having a thickness of about 10 nm, and an Au layer (not shown) having a thickness of about 300 nm, is formed on the reverse surface of the n-type GaN substrate 101 in sequence from the reverse surface of the n-type GaN substrate 101.

The nitride semiconductor laser device according to the second embodiment has a length L1 of about 300 μm to about 800 μm in the direction orthogonal to end surfaces 50 of the resonator ([1-100] direction), and a width W1 of about 200 μm to about 400 μm in the direction along the end surfaces 50 of the resonator ([11-20] direction), as shown in FIG. 24. Side end surfaces 60 orthogonal to the end surfaces 50 of the resonator are formed on the two sides of the ridge 8 of the nitride semiconductor laser device.

Here, in the second embodiment, a notch 120 for dividing the substrate is formed in the vicinity of the side end surface 60 in the reverse surface of the n-type GaN substrate 101 so as to extend in the direction parallel to the ridge 8 ([1-100] direction) as the electric current channel, as shown in FIGS. 21 to 23. The notch 120 is formed by irradiating a YAG laser beam according to the manufacturing method described below. In other words, the notch 120 is formed by causing the GaN constituting the n-type GaN substrate 101 to sublimate by irradiation using a YAG laser beam. The notch 120 is an example of the “substrate-dividing notch” of the present invention. The end parts of the notch 120 are each formed in a position set at a predetermined distance L12 (about 15 μm) from the end surfaces 50 of the resonator, as shown in FIGS. 23 and 24. In other words, the notch 120 is formed to be shorter in length than the length L1 (about 300 μm to about 800 μm) of the nitride semiconductor laser device symmetrically from the center in the [1-100] direction of the nitride semiconductor laser device. The depth d of the deepest part of the notch 120 is about 5 μm to about 80 μm, preferably about 20 μm to about 80 μm, and the width W12 of the notch 120 is about 5 μm.

In the second embodiment, the notch 120 is formed so that the length in the direction parallel to the ridge 8 ([1-100] direction) gradually increases from the bottom of the notch 120 to the reverse surface of the n-type GaN substrate 101, as shown in FIG. 23. Specifically, the two sides (the region from the end parts of the notch 120 to a distance L13 (about 40 μm)) of the notch 120 are formed so as that the depth of the notch 120 gradually increases from the end parts to the center. The shape of the notch 120 is formed so as to be essentially symmetric in relation to the center in the [1-100] direction of the nitride semiconductor laser device when the nitride semiconductor laser device is viewed from the side surface.

In the second embodiment, a notch 120 extending parallel to the ridge 8 as the electric current channel is formed in at least a portion of the vicinity of the side end surface 60 on the reverse surface of the n-type GaN substrate 101 by irradiating a YAG laser beam as described above, whereby the notch 120 can be more deeply formed in comparison with the case in which a notch is formed using a diamond needle. Therefore, the stress applied to the device can be reduced when the n-type GaN substrate 101 is divided by applying stress to the device. For this reason, the substrate can be readily divided along a desired division line because the substrate can be readily divided using the notch 120 as a starting point. A reduction in yield during manufacture of the nitride semiconductor laser device can thereby be limited.

In the second embodiment, the end parts of the notch 120 are formed in a region set at a predetermined distance L12 (about 15 μm) from the end surfaces 50 of the resonator by irradiating a laser beam, whereby laser beam can be prevented from irradiating on the end surfaces 50 of the resonator, which is different from the case in which the notch is formed as far as the end surfaces 50 of the resonator by irradiating a laser beam. Therefore, the region near the end surfaces 50 of the resonator of the n-type GaN substrate 101 can be prevented from becoming damaged due to excessive heat. In other words, in the case that a YAG laser beam is irradiated onto the end surfaces 50 of the resonator, the surface area irradiated by the laser beam is greater in comparison with irradiating YAG laser beam on the reverse surface of the n-type GaN substrate 101. Therefore, the region near the end surfaces 50 of the resonator of the n-type GaN substrate 101 is damaged by an equivalent amount of excessive heat. Accordingly, it is possible to reduce the occurrence of defects in which the end surfaces 50 of the resonator are damaged due to flying chips because the generation of chips in the region near the end surfaces 50 of the resonator of the n-type GaN substrate 101 can be reduced when the n-type GaN substrate 101 is divided using the notch 120 as a starting point. A reduction in the reflectivity of the end surfaces 50 of the resonator can thereby be limited because the region about the periphery of the optical waveguide of the end surfaces 50 of the resonator can be maintained as mirror surface, being positioned below the ridge 8. As a result, a nitride semiconductor laser device having good light emission characteristics can be obtained.

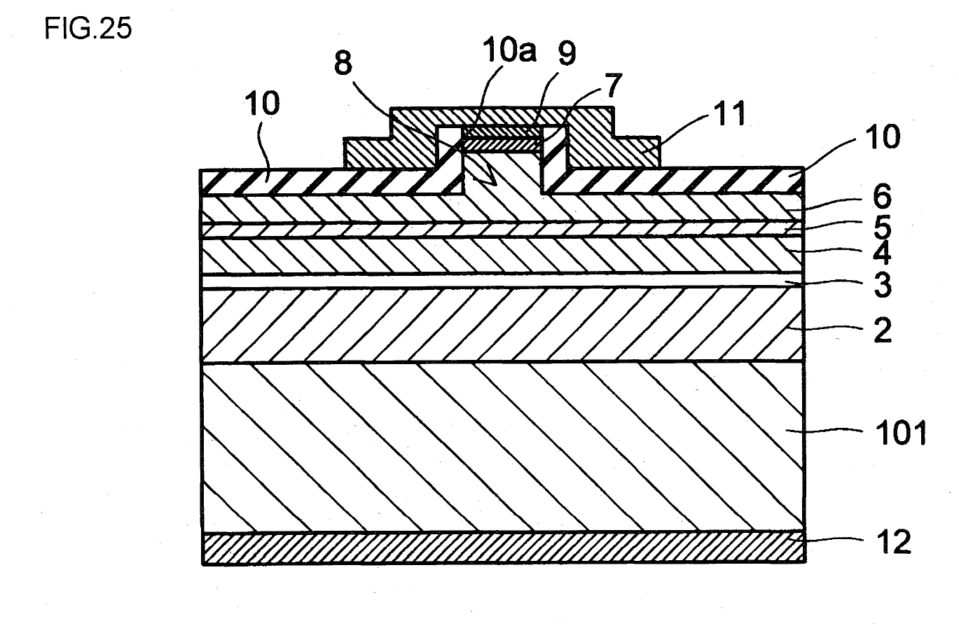

FIGS. 25 to 31 are diagrams for describing the method for manufacturing a nitride semiconductor laser device according to the second embodiment of the present invention shown in FIG. 21. Next, the method for manufacturing a nitride semiconductor laser device according to the second embodiment of the present invention will be described with reference to FIGS. 7 to 12, 21, 23, and 25 to 31.

First, an n-type clad layer 2, an active layer 3, a light-guide layer 4, a cap layer 5, a p-type clad layer 6, and a contact layer 7 are sequentially formed on a n-type GaN substrate 101 using the same manufacturing method as the first embodiment shown in FIG. 7. The composition and thickness of each of the layers 2 to 7 are the same as each of the layers 2 to 7 of the first embodiment.

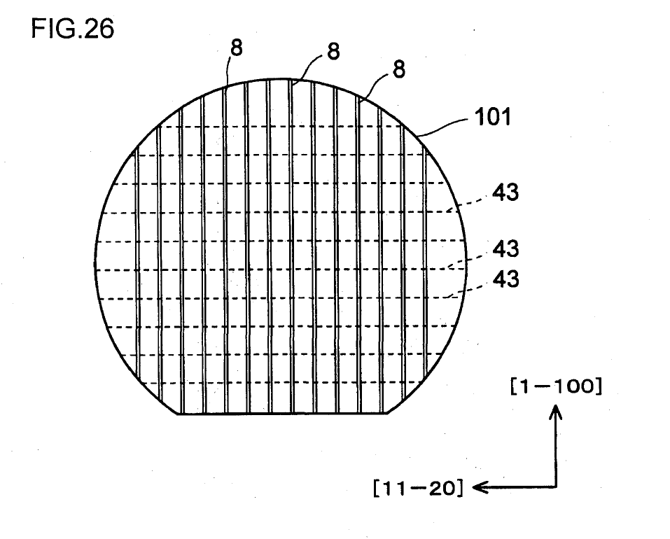

Next, a p-side ohmic electrode 9 composed of a Pt layer (not shown) as the lower layer having a thickness of about 1 nm and a Pd layer (not shown) as the upper layer having a thickness of about 10 nm is formed on the contact layer 7 using the same manufacturing method as the first embodiment shown in FIG. 8. A stripe-shaped (long narrow-shaped) ridge 8 extending in the [1-100] direction is formed using the same manufacturing method as the first embodiment shown in FIGS. 9 and 10. An electric current blocking layer 10 having an aperture 10a, a p-side pad electrode 11 composed of an Au layer, and an n-side electrode 12 are then formed using the same manufacturing method as the first embodiment shown in FIGS. 11 and 12. FIG. 25 shows the device structure obtained in the manner described above. FIG. 26 shows a plan view of the state shown in FIG. 25.

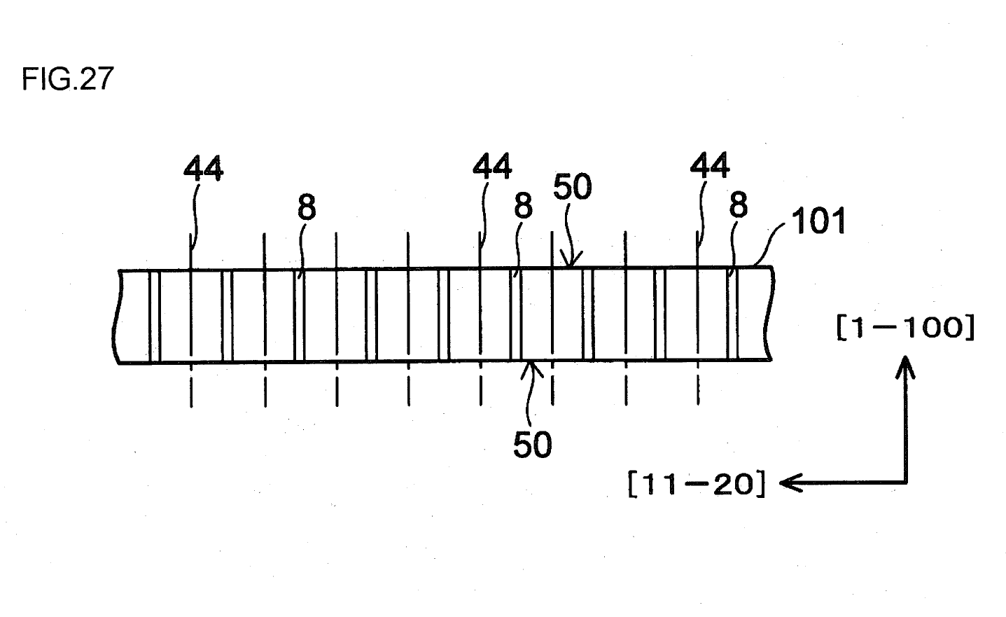

Next, the device is divided into a bar shape by making a primary cleave from the state shown in FIG. 26. The primary cleave can be carried out by cleaving the device at the dotted line 43, which is the direction orthogonal to the ridge 8 ([11-20] direction). The state in which the device is divided into a bar shape by the primary cleave is shown in FIG. 27.

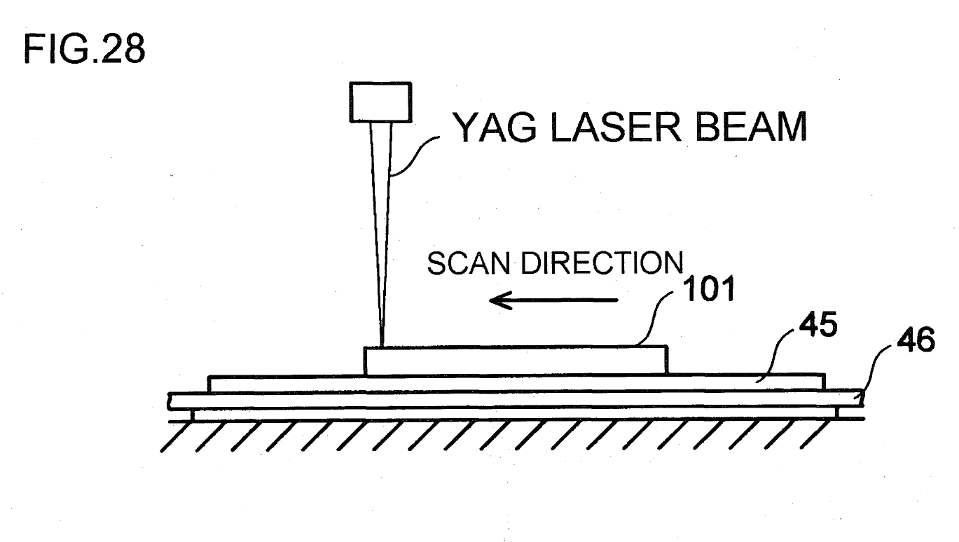

Next, the device is divided (secondary cleave) at an alternate long and short dash line 44, which is the [1-100] direction, between mutually adjacent ridges 8 from the state shown in FIG. 27 to thereby form a chip shape. Specifically, first, a sheet 45 (see FIG. 28) for securing the device to the laser scribe apparatus is applied to the surface (the side on which the nitride semiconductor layers are formed) of the n-type GaN substrate 101 of the device thus divided into a bar shape. Next, the sheet 45 is turned downward and the device (n-type GaN substrate 101) divided into a bar shape is secured to the top of the stage 46 of the laser scribe apparatus, as shown in FIG. 28. In other words, the device divided into a bar shape is mounted on the stage 46 of the laser scribe apparatus so that the reverse surface of the n-type GaN substrate 101 is turned upward.

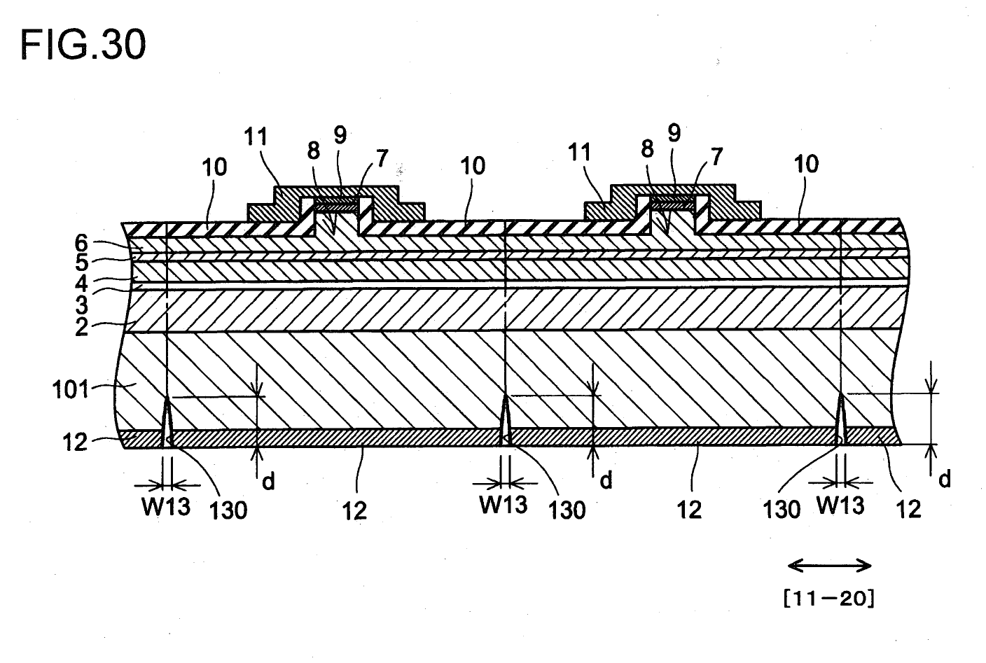

A trench 130 extending in the direction parallel to the ridge 8 ([1-100] direction) as the electric current channel is formed on the reverse surface of the n-type GaN substrate 101 by moving the n-type GaN substrate 101 in the [1-100] direction while YAG laser beam is irradiated. The trench 130 has a cross-sectional V-shape, as shown in FIG. 30, and is formed so that the depth d of the deepest part is about 5 μm to about 80 μm, preferably about 20 μm to about 80 μm, and the width W13 of the aperture end is about 10 μm.

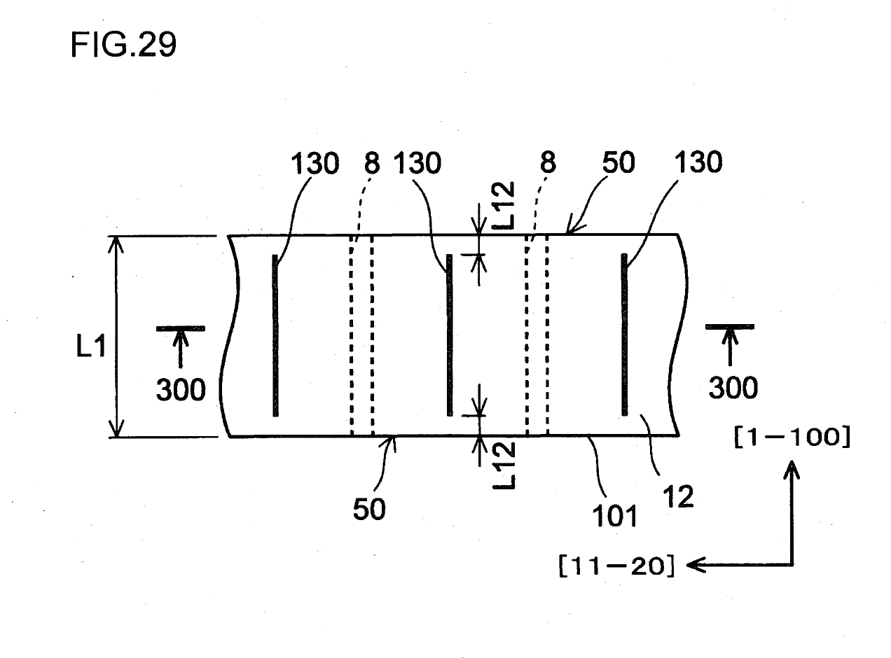

Here, in the second embodiment, the end parts of the trench 130 are formed in positions set at a predetermined distance L12 (about 15 μm) from each of the end surfaces 50 of the resonator by irradiating a YAG laser beam, as shown in FIG. 29. In other words, the trench 130 is formed to a length that is less than the length L1 (about 300 μm to about 800 μm) between the end surfaces 50 of the resonator symmetrically from the center in the [1-100] direction.

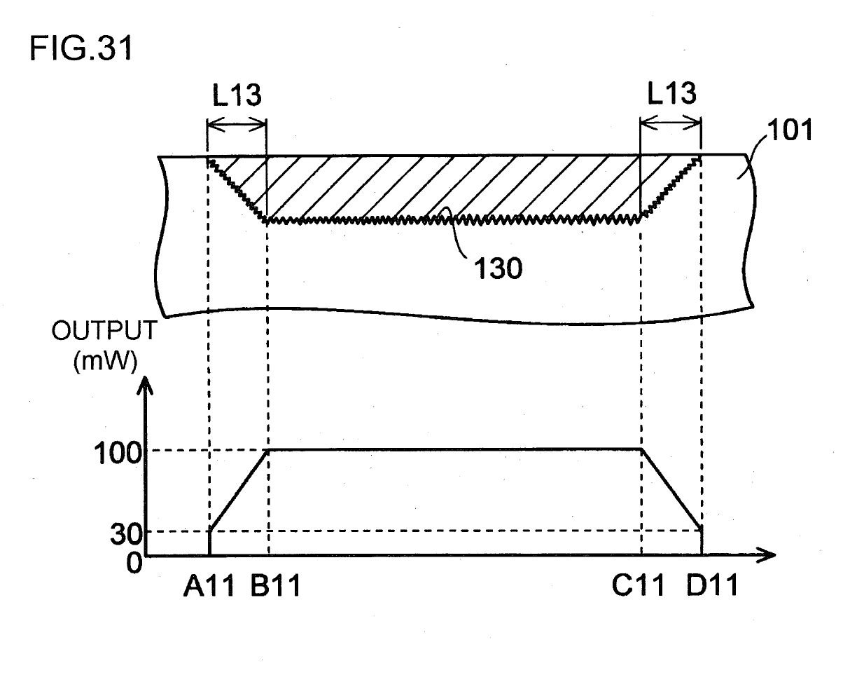

In the second embodiment, the length of the trench 130 in the direction parallel to the ridge 8 ([1-100] direction) is formed so as to gradually increase from the bottom of the trench 130 toward the reverse surface of the n-type GaN substrate 101, as shown in FIG. 23. Specifically, the YAG laser beam is irradiated onto the reverse surface of the n-type GaN substrate 101 while the output of the YAG laser beam is gradually increased to between about 30 mW to about 100 mW from the starting position A11 (one end part of the trench 30) where the YAG laser beam is irradiated to a position B11 apart from the position A11 at a distance L13 (about 40 μm), as shown in FIG. 31. Also, the YAG laser beam is irradiated onto the reverse surface of the n-type GaN substrate 101 while the output of the YAG laser beam is gradually reduced to between about 100 mW to about 30 mW from a position C11 at distance L13 (about 40 μm) from the end position D11 (other end part of the trench 30) where the YAG laser beam is irradiated to the end position D11. A YAG laser beam is irradiated onto the reverse surface of the n-type GaN substrate 101 at a constant output of about 100 mW between the position B11 and the position C11. The two end parts (a distance L13 (about 40 μm) from each of the end parts of the trench 130) of the trench 130 are thereby formed so that the depth of the trench 130 gradually increases from the end parts toward the center. In other words, a trench 130 having a boat shape is formed. The conditions (output, frequency, focal position, substrate movement speed, and the like) for irradiating a YAG laser beam can be arbitrarily modified in order to obtain a desired trench shape.

Lastly, stress is applied to the device and the n-type GaN substrate 101 is divided (cleaved) along the trench 130 by pressing a breaker blade from the upper surface (the surface in which the trench 130 is not formed) of the n-type GaN substrate 101. The device thus divided into a bar shape is thereby divided (secondary cleave) into a chip shape. A side end surface 60 orthogonal to the end surfaces 50 of the resonator is formed by dividing the n-type GaN substrate 101 along the trench 130, and the notch 120 described above is formed in the vicinity of the side end surface 60. In this manner, a nitride semiconductor laser device according to the second embodiment such as that shown in FIG. 21 is formed.

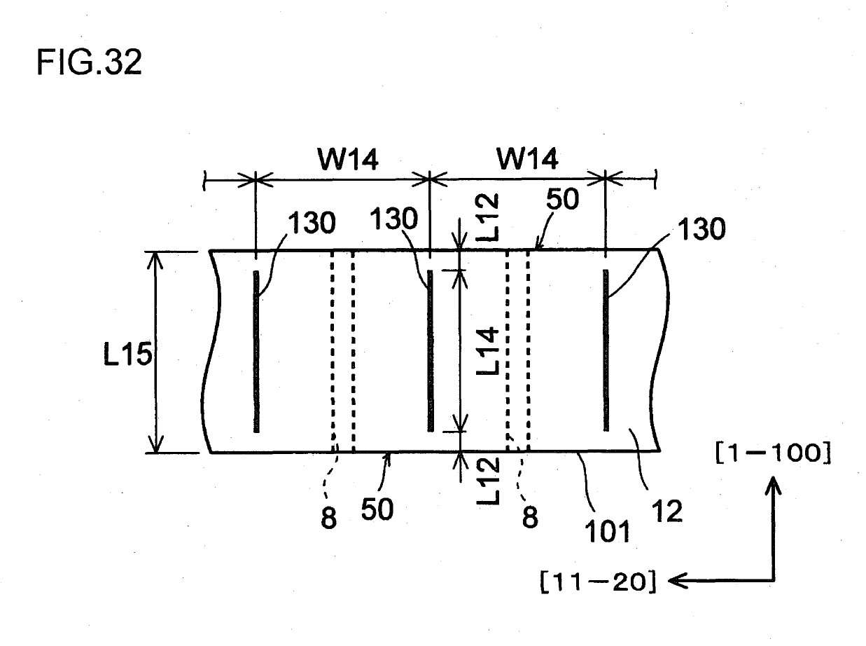

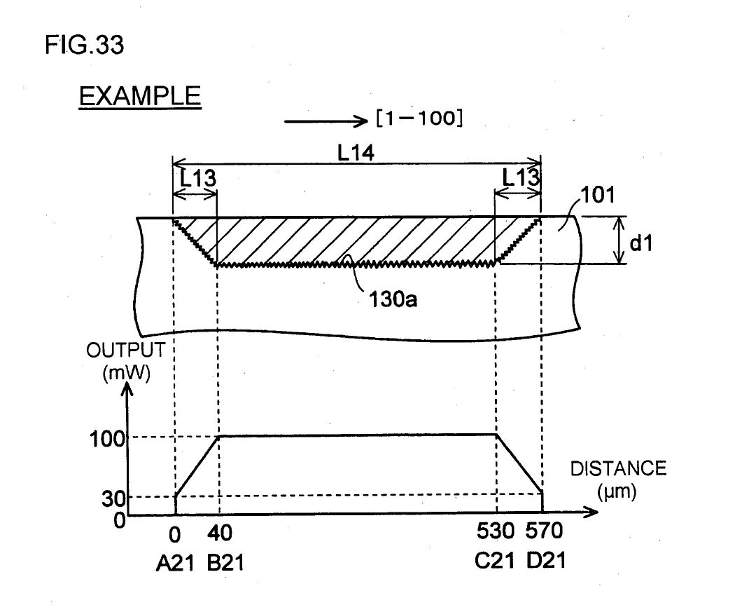

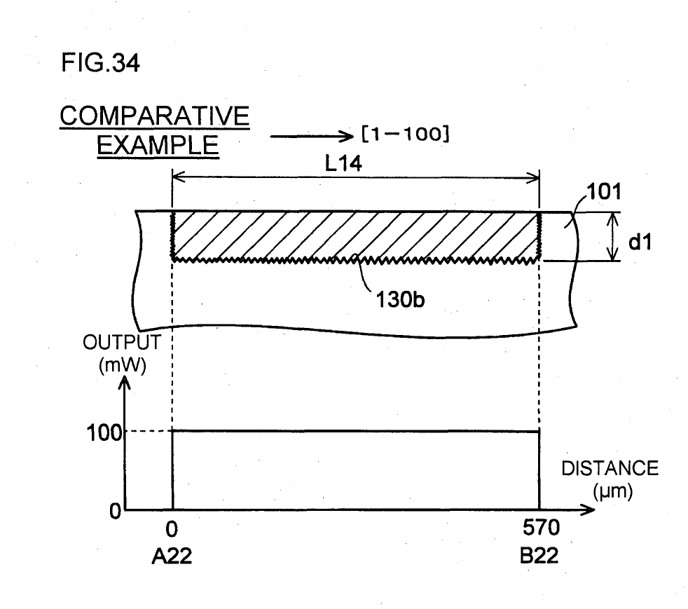

Next, an experiment carried out in order to confirm the effects of the second embodiment described above will be described. In the experiment, the yield ratio was measured for cases in which the trench shape was modified in order to confirm the effect that the trench shape has on the yield at the time of the secondary cleave of the nitride semiconductor laser device. FIG. 32 is a plan view for describing the formation position of the trench and the device shape. FIG. 33 is a view for describing the shape of the trench according to an example. FIG. 34 is a view for describing the shape of the trench according to a comparative example. The vertical axes of the graphs in FIGS. 33 and 34 represent the output (mW) of the YAG laser beam, and the horizontal axes represent the distance (μm) from the starting position of the trench.

A nitride semiconductor layer and an electrode layer were formed in the example and the comparative example using the same manufacturing method as the method for manufacturing the nitride semiconductor laser device described above. The trench 130 was formed in the example and the comparative example so as to extend in the [1-100] direction by irradiating a YAG laser beam on the reverse surface of the n-type GaN substrate 101, as shown in FIG. 32. The length L14 of the trench 130 was set to about 570 μm for the example and the comparative example, and the end parts of the trench 130 were formed in a position set at a distance L12 of about 15 μm from the end surfaces 50 of the resonator. The distance L15 between the end surfaces 50 of the resonator was set to about 600 μm in the example and the comparative example, and the distance W14 between trenches 130 was set to about 200 μm. The depth d1 of the deepest part of the trench 130 was set to about 40 μm in the example and the comparative example, as shown in FIGS. 33 and 34.

The conditions for irradiating the YAG laser beam were the same for the example and the comparative example, i.e., a frequency of 50 kHz, a substrate movement speed of 5 mm/s, and a focal position of −20 μm. In other words, the focal point was set to meet at a position 20 μm above (the direction opposite from the n-type GaN substrate 101) the surface of the n-side electrode 12. A laser scriber WSF4000 manufactured by Opto Systems was used as the laser scribe apparatus for forming the trench 130.

The shape of the trench 130a (30) according to the example was set to a boat shape in the same manner as the second embodiment described above, as shown in FIG. 33. Specifically, the YAG laser beam was irradiated onto the reverse surface of the n-type GaN substrate 101 while the output of the YAG laser beam was gradually increased to between about 30 mW to about 100 mW from the starting position A21 (one end part of the trench 130a) where the YAG laser beam was irradiated to a position B21 apart from the position A21 at a distance L13 (about 40 μm). The YAG laser beam was irradiated onto the reverse surface of the n-type GaN substrate 101 while the output of the YAG laser beam was gradually reduced to between about 100 mW to about 30 mW from a position C21 at distance L13 (about 40 μm) from the end position D21 (other end part of the trench 130a) where the YAG laser beam was irradiated to the end position D21. A YAG laser beam was irradiated onto the reverse surface of the n-type GaN substrate 101 at a constant output of about 100 mW between the position B21 and the position C21. The two end parts (a region at distance L13 (about 40 μm) from the end parts of the trench 130a) of the trench 130a were thereby formed so that the depth of the trench 130a gradually increases from the end parts toward the center.

The shape of the trench 130b (30) according to the comparative example was formed so as to be a rectangular shape, as shown in FIG. 34. In other words, a YAG laser beam was irradiated onto the reverse surface of the n-type GaN substrate 101 at a constant output of about 100 mW from a starting position A22 (one end of a trench 130b) where the YAG laser beam was irradiated to an end point B22 (other end of the trench 130b), whereby the length L14 of the trench 30b in the [1-100] direction was formed so that the bottom of the trench 130b and the aperture end of the trench 130b had substantially the same length L14.

The blade of a breaker was pressed from the upper surface (the surface in which the trench 130 is not formed) of the n-type GaN substrate 101 of the devices according to the example and the comparative example formed in the manner described above, and the n-type GaN substrate 101 was divided (cleaved) into a chip shape along the trench 130. The number of defective divisions (defective cleaves) at the time of division was counted and the yield ratio (%) of the secondary cleave was calculated. The reference for determining a defective division (defective cleave) was based on the presence of chipping in the p-side pad electrode 11. In other words, a defective division was determined in the case that chipping was present in the p-side pad electrode 11.

As a result, the yield ratio of the devices having the trench shape of the comparative example was 92.4%. In contrast, the yield ratio of the devices having the trench shape of the example was 96.0%, which was greater than that of the comparative example. It was thereby confirmed that the yield ratio is improved without the occurrence of chipping by making the shape of the trench 130 to be a boat shape, in comparison with the case that the shape of the trench 130 was a rectangular shape.

In the method for manufacturing a nitride semiconductor laser device according to the second embodiment, the trench 130 is formed extending in the direction parallel to the ridge 8 on the reverse surface of the n-type GaN substrate 101 by irradiating a YAG laser beam in the manner described above, whereby the trench 130 can be more deeply formed in comparison with the case in which the trench is formed on the reverse surface of the n-type GaN substrate 101 using a diamond needle, and it is also possible to reduce the stress applied to the device when the n-type GaN substrate 101 is divided by applying stress to the device. Accordingly, the substrate can be divided in a simple manner along a desired division line because the n-type GaN substrate 101 can be readily divided using the trench 130 thus formed as the starting point. A reduction in yield can thereby be limited during manufacture of the nitride semiconductor laser device.

In the second embodiment, the end parts of the trench 130 are formed in the reverse surface of the n-type GaN substrate 101, i.e., in a region set at a predetermined distance L12 (about 15 μm) from the end surfaces 50 of the resonator by irradiating a laser beam, whereby laser beam can be prevented from irradiating to the end surfaces 50 of the resonator, which is different from the case in which the trench is formed as far as the end surfaces 50 of the resonator by irradiating a laser beam. Therefore, the region near the end surfaces 50 of the resonator of the n-type GaN substrate 101 can be prevented from being damaged due to excessive heat. Accordingly, it is possible to reduce the occurrence of defects in which the end surfaces 50 of the resonator are damaged due to flying chips because the generation of chips in the region near the end surfaces 50 of the resonator of the n-type GaN substrate 101 can be reduced when the n-type GaN substrate 101 is divided using the trench 130 as a starting point. As a result, a reduction in the reflectivity of the end surfaces 50 of the resonator can thereby be limited and a nitride semiconductor laser device having good light emission characteristics can be obtained because the region about the periphery of the optical waveguide of the end surfaces 50 of the resonator can be maintained as a mirror surface.

In the second embodiment, the region near the end surfaces 50 of the resonator of the n-type GaN substrate 101 can be prevented from being damaged due to excessive heat by forming the end parts of the trench 130 in the reverse surface of the n-type GaN substrate 101, which is a region set at a predetermined distance L12 (about 15 μm) from the end surfaces 50 of the resonator by irradiating a YAG laser beam. It is therefore possible to reduce the occurrence of defects in which dust, chips, and other unwanted matter are generated during formation of the trench 130 in the region near the end surfaces 50 of the resonator of the n-type GaN substrate 101 due to the region near the end surfaces 50 of the resonator of the n-type GaN substrate 101 being damaged by excessive heat. For this reason, it is possible to reduce the occurrence of defects in which the end surfaces 50 of the resonator are damaged by deposits of unwanted matter because dust, chips, and other unwanted matter generated during formation of the trench 130 can be prevented from being deposited on the end surfaces 50 of the resonator. Since the region near the optical waveguide of the end surfaces 50 of the resonator can thereby be maintained as a mirror surface, a reduction in the reflectivity of the end surfaces 50 of the resonator can be limited. As a result, good light emission characteristics can be obtained as well.

In the second embodiment, YAG laser beam can be prevented from irradiating the adhesive sheet 45 or the like for securing the device applied to the lower surface (the surface on the opposite side of the surface in which the trench 130 is formed) of the device because the irradiation of the YAG laser beam can be stopped at the position of the end parts of the trench 130 by forming the end parts of the trench 130 in a region set at a predetermined distance L12 (about 15 μm) from the end surfaces 50 of the resonator. Accordingly, the sheet 45 or the like can be prevented from being irradiated by the YAG laser beam, and the sheet 45 or the like can be prevented from being burned. Therefore, the occurrence of unwanted matter or the like due to the sheet 45 or the like being burned can be prevented. Since it is thereby possible to reduce deposits of unwanted matter or the like generated by the sheet 45 or the like being burned on the end surfaces 50 of the resonator, it is possible to reduce the occurrence of defects in which the end surfaces 50 of the resonator are damaged due to deposits of unwanted matter or the like on the end surfaces 50 of the resonator. As a result, a reduction in the reflectivity of the end surfaces 50 of the resonator can thereby be limited because the region about the periphery of the optical waveguide of the end surfaces 50 of the resonator can be maintained as a mirror surface.

In the second embodiment, the length of the trench 130 in the direction parallel to the ridge 8 ([1-100] direction) as the electric current channel is formed so as to gradually increase from the bottom of the trench 130 toward the reverse surface of the n-type GaN substrate 101, whereby the n-type GaN substrate 101 can be readily divided along a desired division line and the occurrence of chipping at the edges after division can be reduced in a simple manner even when the end parts of the trench 130 are formed in a region set at a predetermined distance L12 (about 15 μm) from the end surfaces 50 of the resonator because the n-type GaN substrate 101 can be more readily divided using the trench 130 as a starting point. A reduction in yield during manufacture can thereby be limited in a simple manner and a nitride semiconductor laser device having good light emission characteristics can be readily manufactured.

In the second embodiment, the crystallographic axes of the n-type GaN substrate 101 and the plurality of nitride semiconductor layers formed on the n-type GaN substrate 101 can be made to match by using the n-type GaN substrate 101 as a substrate. Therefore, the n-type GaN substrate 101 and the nitride semiconductor layers can be readily divided at a uniform crystallographic axis. The nitride semiconductor laser device can thereby be readily divided along a desired division line and the occurrence of chipping at the edges following division can be more readily reduced.

The embodiments disclosed herein are examples on all points and should not be considered as limitations thereto. The scope of the present invention is indicated by the claims and not by the description of the embodiments described above, and all modifications in the purport and scope of the claims are included.

For example, in the first and second embodiments, an example was shown in which an n-type GaN substrate was used as the substrate, but the present invention is not limited thereto, and a substrate that is not an n-type GaN substrate, such as a substrate composed of InGaN, AlGaN, AlGaInN, or the like, may also be used.

In the first and second embodiments, an example was shown in which the nitride semiconductor layers were formed by crystal growth using MOCVD, but the present invention is not limited thereto, and the nitride semiconductor layers may be formed by crystal growth using a method other than MOCVD. Examples of methods other than MOCVD can include HYPE and gas source MBE (Molecular Beam Epitaxy).

In the first embodiment described above, an example was shown in which a notch was formed in only one of the side end surfaces of a ridge, but the present invention is not limited thereto, and a configuration is also possible in which the notch is formed in the two side-end surfaces of a ridge.

In the first embodiment described above, an example was shown in which the trench and the notch are formed so that the length in the direction orthogonal to the ridge ([11-20] direction) gradually increases from the bottom to the upper surface of the n-type GaN substrate, but the present invention is not limited thereto, and the trench and the notch may be formed so that the length in the direction orthogonal to the ridge ([11-20] direction) is substantially the same length in the bottom and the upper surface of the n-type GaN substrate. In other words, the trench and notch may be formed in a rectangular shape.

In the first embodiment described above, an example was shown in which the trench was formed symmetrically from the center in the [11-20] direction, but the present invention is not limited thereto, and the trench may be formed so that the trench is asymmetric from the center in the [11-20] direction.

In the first embodiment, a case was described in which the trench was formed so as to transverse a high-displacement density region in the region between ridges in which the high-displacement density region of the n-type GaN substrate is provided, but the present invention is not limited thereto, and a trench may also be formed in a region between ridges in which a high-displacement density region is not provided.

In the first embodiment described above, a case was described in which an n-type GaN substrate was used that had a periodically arranged high-displacement density region and low-displacement density region, but the present invention is not limited thereto, and an n-type GaN substrate may be used other than an n-type GaN substrate on which a high-displacement density region and a low-displacement density region are periodically arranged. A substrate that is not an n-type GaN substrate, such as a substrate composed of InGaN, AlGaN, AlGaInN, or the like, may also be used.

In the first embodiment described above, a case was described in which the ridge is formed so as to extend in the [1-100] direction, and the notch and the trench are formed so as to extend in the [11-20] direction, but the present invention is not limited thereto, and the directions may be crystallographically equivalent directions. In other words, the ridge may be formed so as to extend in the direction expressed by <1-100>, and the notch and the trench may be formed so as to extend in the direction expressed by <11-20>.

In the second embodiment, an example was shown in which the end parts of the trench and the notch are formed in a region set at about 15 μm from the end surfaces of the resonator, but the present invention is not limited thereto, and the end parts of the trench and the notch may be in a region set at a distance other than about 15 μm from the end surfaces of the resonator, as long as the end parts of the trench and the notch do not reach the end surfaces of the resonator.

In the second embodiment described above, an example was shown in which the trench and the notch are formed symmetrically in relation to the center in the [1-100] direction, but the present invention is not limited thereto, and the trench and the notch may be formed so that the trench and the notch are asymmetric in relation to the center in the [1-100] direction.

In the second embodiment, an example was shown in which the trench and the notch are formed so that the length in the direction parallel to the ridge ([1-100] direction) gradually increases from the bottom to the reverse surface of the n-type GaN substrate, but the present invention is not limited thereto, and the trench and the notch may be formed so that the length in the direction parallel to the ridge ([1-100] direction) is substantially the same length in the bottom and the reverse surface of the n-type GaN substrate.

In the second embodiment described above, an example was shown in which the shape of the notch is configured so as to be essentially symmetric in relation to the center in the [1-100] direction of the nitride semiconductor laser device when viewed from the side surface of the nitride semiconductor laser device, but the present invention is not limited thereto, and the shape of the notch may be configured so as to be asymmetric in relation to the center in the [1-100] direction of the nitride semiconductor laser device.

In the second embodiment, a case was described in which the ridge, the notch, and the trench are formed so as to extend in the [1-100] direction, and end surfaces of the resonator are formed in the direction along the [11-20] direction, but the present invention is not limited thereto, and the directions may be crystallographically equivalent directions. In other words, the ridge, the notch, and the trench may be formed along the direction expressed by <1-100>, and end surfaces of the resonator may be formed along the direction expressed by <11-20>.

In the second embodiment, an example was shown in which the nitride semiconductor layers were layered so that the surface is the (0001) plane, but the present invention is not limited thereto, and the nitride semiconductor layers may be layered so that the surface is a plane other than the (0001) plane.

In the second embodiment described above, an n-type GaN substrate may be used in which a high-displacement density region and a low-displacement density region are periodically arranged.

The device may be separated using both the primary cleave method according to the first embodiment and the secondary cleave method according to the second embodiment. In such a case, it is possible to more effectively limit a reduction in yield and to obtain a nitride semiconductor laser device having better light emission characteristics.

1. A method for manufacturing a nitride semiconductor laser device, characterized in comprising:
a step for forming a plurality of nitride semiconductor layers including a light-emitting layer on an upper surface of a substrate;
a step for forming an electric current channel extending in a predetermined direction on at least one of said plurality of nitride semiconductor layers;
a step for forming a trench extending in a direction orthogonal to said electric current channel on the upper surface of said substrate by irradiating laser beam on the upper surface of said nitride semiconductor layers; and
a step for forming end surfaces of a resonator by dividing said substrate using said trench as a starting point, wherein
the step for forming said trench includes a step for forming end parts of said trench in a region set at a predetermined distance from said electric current channel.

2. The method for manufacturing a nitride semiconductor laser device according to claim 1, characterized in that the step for forming said trench includes a step for forming the length of said trench in a direction orthogonal to said electric current channel so that the length gradually increases from the bottom of said trench toward the upper surface of said substrate.

3. The method for manufacturing a nitride semiconductor laser device according to claim 1, characterized in that said substrate includes a nitride semiconductor substrate.

4. The method for manufacturing a nitride semiconductor laser device according to claim 2, characterized in that said substrate includes a nitride semiconductor substrate.

5. The method for manufacturing a nitride semiconductor laser device according to claim 3, characterized in that said nitride semiconductor substrate has a periodically arranged high-displacement density region and low-displacement density region that extend along said electric current channel;
the step for forming said electric current channel includes a step for forming said electric current channel on said low-displacement density region of said nitride semiconductor substrate; and
the step for forming said trench includes a step for forming said trench so as to be transverse to said high-displacement density region by irradiating laser beam.

6. The method for manufacturing a nitride semiconductor laser device according to claim 4,characterized in that said nitride semiconductor substrate has a periodically arranged high-displacement density region and low-displacement density region that extend along said electric current channel;
the step for forming said electric current channel includes a step for forming said electric current channel on said low-displacement density region of said nitride semiconductor substrate; and
the step for forming said trench includes a step for forming said trench so as to be transverse to said high-displacement density region by irradiating laser beam.

7. A method for manufacturing a nitride semiconductor laser device characterized in comprising:
a step for forming a plurality of nitride semiconductor layers including a light-emitting layer on a substrate;
a step for forming an electric current channel extending in a predetermined direction on at least one of said plurality of nitride semiconductor layers;
a step for forming a pair of end surfaces of a resonator orthogonal to said electric current channel;
a step for forming a trench that extends parallel to said electric current channel part on the reverse surface of said substrate by irradiating laser beam; and
a step for dividing said substrate using said trench as a starting point, wherein
said step for forming said trench includes a step for forming end parts of said trench in a region set at a predetermined distance from said end surfaces of the resonator.

8. The method for manufacturing a nitride semiconductor laser device according to claim 7,
characterized in that the step for forming said trench includes a step for forming the length of said trench in the direction parallel to said electric current channel part so that the length gradually increases from the bottom of said trench toward the reverse surface of said substrate.

9. The method for manufacturing a nitride semiconductor laser device according to claim 7, characterized in that said substrate includes a nitride semiconductor substrate.

10. The method for manufacturing a nitride semiconductor laser device according to claim 8,
characterized in that said substrate includes a nitride semiconductor substrate.

11. A nitride semiconductor laser device characterized in comprising:
a plurality of nitride semiconductor layers including a light-emitting layer, the nitride semiconductor layers being formed on a substrate;
an electric current channel extending in a predetermined direction, the electric current channel being formed on at least one of said plurality of nitride semiconductor layers;
a pair of end surfaces of a resonator orthogonal to said electric current channel and
a substrate-dividing notch formed in at least a part of the vicinity of said end surfaces of a resonator in an upper surface of said substrate by irradiating a laser beam, wherein
the end parts of said substrate-dividing notch are formed in a region set at a predetermined distance from said electric current channel.

12. The nitride semiconductor laser device according to claim 11, characterized in that said substrate-dividing notch is configured so that the length in the direction orthogonal to said electric current channel gradually increases from the bottom of said substrate-dividing notch toward the upper surface of said substrate.

13. The nitride semiconductor laser device according to claim 11, characterized in that said substrate includes a nitride semiconductor substrate.

14. A nitride semiconductor laser device, characterized in comprising:
a plurality of nitride semiconductor layers including a light-emitting layer, the nitride semiconductor layers being formed on a substrate;
an electric current channel extending in a predetermined direction, the electric current channel being formed on at least one of said plurality of nitride semiconductor layers;
a pair of end surfaces of a resonator orthogonal to said electric current channel;
a side end surface orthogonal to said end surfaces of the resonator; and
a substrate-dividing notch extending parallel to said electric current channel, the substrate-dividing notch being formed in at least a part of the vicinity of said side end surface in a reverse surface of said substrate by irradiating a laser beam, wherein
the end parts of said substrate-dividing notch are formed in a region set at a predetermined distance from said end surfaces of the resonator.

15. The nitride semiconductor laser device according to claim 14, characterized in that said substrate-dividing notch is configured so that the length in the direction parallel to said electric current channel gradually increases from the bottom of said substrate-dividing notch toward the reverse surface of said substrate.

16. The nitride semiconductor laser device according to claim 14, characterized in that said substrate includes a nitride semiconductor substrate.
